(19) United States
(12) Patent Application Publication
(10) Pub. No.: US 2024/0057439 A1
(43) Pub. Date: Feb. 15, 2024

(54) DISPLAY DEVICE AND MANUFACTURING METHOD THEREOF

(71) Applicant: Samsung Display Co., LTD., Yongin-si (KR)

(72) Inventors: Jun Young LEE, Yongin-si (KR); Young Do KIM, Yongin-si (KR); Jeong Weon SEO, Yongin-si (KR); Jun Woo YOU, Yongin-si (KR); Jeong Ho HWANG, Yongin-si (KR)

(21) Appl. No.: 18/229,581

(22) Filed: Aug. 2, 2023

(30) Foreign Application Priority Data
Aug. 11, 2022 (KR) 10-2022-0100823

(51) Int. Cl. H10K 59/65; H10K 59/121; H10K 71/12; H10K 59/80

(52) U.S. Cl. CPC H10K 59/65; H10K 59/1213; H10K 71/12; H10K 59/873

(57) ABSTRACT

A display device includes: a display panel that includes a substrate including a display area and a non-display area and a plurality of pixels in the display area; a cover panel directly on a rear surface of the substrate and including an opening exposing at least one area of the substrate; a sensor provided within the opening of the cover panel; a circuit board coupled to one side of an upper surface of the substrate and electrically connected to the pixels; and a receiving member configured to receive the display panel, the cover panel, and the circuit board, wherein the cover panel includes a photo-curable resin or a thermo-curable resin.

### CROSS-REFERENCE TO RELATED APPLICATION

The present application claims priority to and the benefit of Korean Patent Application No. 10-2022-0100823 filed in the Korean Intellectual Property Office on Aug. 11, 2022, the entire disclosure of which is incorporated herein by reference.

### BACKGROUND

### 1. Field

Aspects of some embodiments of the present disclosure relate to a display device and a manufacturing method thereof.

### 2. Description of the Related Art

Recently, as interest in information displays is increasing, research and development for display devices are continuously conducted.

The above information disclosed in this Background section is only for enhancement of understanding of the background and therefore the information discussed in this Background section does not necessarily constitute prior art.

### SUMMARY

Aspects of some embodiments of the present disclosure include a display device and a manufacturing method thereof that may be formed by curing a coating solution applied on a rear surface of a substrate while avoiding a sensor mounting area of a display panel and may protect the display panel by using a cover panel including an opening corresponding to the sensor mounting area.

According to some embodiments, a display device includes: a display panel that includes a substrate including a display area and a non-display area and a plurality of pixels provided in the display area; a cover panel directly dispose on a rear surface of the substrate and including an opening exposing at least one area of the substrate; a sensor provided within the opening of the cover panel; a circuit board coupled to one side of an upper surface of the substrate and electrically connected to the pixels; and a receiving member that receives the display panel, the cover panel, and the circuit board. The cover panel may include a photo-curable resin or a thermo-curable resin.

According to some embodiments, the sensor may include at least one of a camera, a proximity sensor, an illuminance sensor, a gesture sensor, an infrared sensor, a fingerprint recognition sensor, or a biometric sensor.

According to some embodiments, each of the pixels may include: a pixel circuit layer including at least one transistor located on an upper surface of the substrate; and a display element layer including a light emitting element electrically connected to the transistor.

According to some embodiments, in a manufacturing method of a display device, the method includes: preparing a display panel including a plurality of pixels located on an upper surface of a substrate; seating the display panel on a stage so that a rear surface of the substrate facing the upper surface of the substrate faces upward; applying a coating solution on the rear surface of the substrate while avoiding a specific area on the rear surface of the substrate while a first supplier including a plurality of first nozzles is positioned above the rear surface of the substrate and moved along a first direction; applying the coating solution on an uncoated area to which the coating solution is not applied by the first supplier while avoiding a specific area of the substrate while a second supplier including a plurality of second nozzles moves along a second crossing the first direction; and curing the coating solution to form a cover panel including an opening corresponding to the specific area on the rear surface of the substrate.

According to some embodiments, the rear surface of the substrate may include a first edge and a second edge facing each other in the first direction, and includes a third edge and a fourth edge facing each other in the second direction.

According to some embodiments, the coating solution may include a curable resin.

According to some embodiments, the curable resin may include a thermosetting resin or a photocurable resin.

According to some embodiments, the first supplier may include a first slit head moving in the first direction, and the first nozzles positioned on a lower surface of the first slit head and individually controlled to apply the coating solution to a predetermined area on the rear surface of the substrate.

According to some embodiments, as the first slit head moves from the first edge to the second edge along the first direction, at least one or more of the first nozzles may apply the coating solution to a predetermined area of the rear surface of the substrate.

According to some embodiments, when the coating solution is applied to the predetermined area of the rear surface of the substrate, the first slit head may move from the second edge to the first edge and then may move in the second direction.

According to some embodiments, when the first slit head moves from the first edge to the second edge along the first direction, the first nozzles may be maintained in an turned-off state in the specific area, and at least one or more of the first nozzles may be turned on after passing the specific area to apply the coating solution to a predetermined area of the rear surface of the substrate.

According to some embodiments, when the specific area includes a first specific area and a second specific area that are positioned on a same line in the first direction and are spaced apart from each other, and when the first slit head moves from the first edge to the second edge along the first direction, the first nozzles may be maintained in an turned-off state and then may pass through the first specific area, and at least one or more of the first nozzles may be turned on to apply the coating solution to the rear surface of the substrate and may be turned off before the second specific area.

According to some embodiments, the second supplier may include a second slit head moving in the second direction, and the second nozzles positioned on a lower surface of the second slit head and individually controlled to apply the coating solution to the uncoated area.

According to some embodiments, as the second slit head moves from the third edge to the fourth edge along the second direction, at least one or more of the second nozzles may apply the coating solution to the uncoated area.

According to some embodiments, when the coating solution is applied to the uncoated area, the second slit head may move from the fourth edge to the third edge and then may move in the first direction.

According to some embodiments, when the second slit head moves from the third edge to the fourth edge along the second direction, at least one of the second nozzles positioned to correspond to the uncoated area may be turned on to apply the coating solution to the uncoated area.

According to some embodiments, when the second slit head moves from the third edge to the fourth edge along the second direction, the second nozzles may be maintained in an turned-off state in the specific area, and at least one of the second nozzles may be turned on after passing the specific area to apply the coating solution to the uncoated area.

According to some embodiments, the first direction may be one of a vertical direction and a horizontal direction, and the second direction may be the other of the vertical direction and the horizontal direction.

According to some embodiments, the manufacturing method of the display device may further include attaching a circuit board to one side of an upper surface thereof facing the rear surface of the substrate; and inserting a sensor into the opening.

According to some embodiments, the sensor may include at least one of a camera, a proximity sensor, an illuminance sensor, a gesture sensor, an infrared sensor, a fingerprint recognition sensor, or a biometric sensor.

According to the display device and the method of manufacturing thereof according to some embodiments, by using a plurality of first slit nozzles that avoids a sensor part mounting area of a display panel while moving in a first direction and applies a coating solution only to a target area, and a plurality of second slit nozzles that avoids the sensor part mounting area while moving in a second direction and applies the coating solution to an uncoated area in which the coating solution is not applied by the first slit nozzles, it is possible to form a cover panel made of a high-viscosity material on a rear surface of the display panel (for example, a substrate).

The above-mentioned cover panel may protect the rear surface of the display panel, may block static electricity, and may dissipate heat generated from heating members. The cover panel may replace a protective member (for example, a cushion layer) for protecting the rear surface of the display panel, a static electricity shielding member for blocking static electricity, and a heat dissipating member for dissipating heat generated from heat generating members, so that the protective member, the shielding member, and the heat dissipating member may be omitted. Accordingly, it is possible to reduce a manufacturing cost of a display device and to further improve process efficiency.

Characteristics of embodiments according to the present disclosure are not limited by what is illustrated in the above, and more various effects are included in the present specification.

### BRIEF DESCRIPTION OF THE DRAWINGS

FIG. 1 illustrates a schematic perspective view of a display device according to one or more embodiments.

FIG. 2 illustrates a schematic exploded perspective view of a display device according to one or more embodiments.

FIG. 3 illustrates a schematic top plan view of a display module according to one or more embodiments.

FIG. 4 illustrates a schematic cross-sectional view of the display module of FIG. 3.

FIG. 5 illustrates a schematic cross-sectional view of a display panel according to one or more embodiments.

FIG. 6 illustrates a schematic circuit diagram of an electrical connection relationship of constituent elements included in each of pixels illustrated in FIG. 3.

FIG. 7 illustrates a schematic cross-sectional view taken along line I-I′ of FIG. 2.

FIG. 8 illustrates a schematic top plan view of a cover panel of FIG. 7.

FIG. 9 illustrates a schematic perspective view of a coating apparatus for forming the cover panel of FIG. 8.

FIG. 10 schematically illustrates that a coating solution is applied by a first supplier of FIG. 9.

FIG. 11 illustrates a schematic perspective view of a first slit head of FIG. 9.

FIG. 12 illustrates illustrated schematic perspective view of a second slit head of FIG. 9.

FIG. 13A to FIG. 13K illustrate schematic drawings for sequentially explaining a method of forming a cover panel by using the coating apparatus of FIG. 9.

FIG. 14 illustrates a flowchart of a manufacturing method of the display device of FIG. 2.

### DETAILED DESCRIPTION

Because the present disclosure may be variously modified and have various forms, embodiments will be illustrated and described in detail in the following. This, however, by no means restricts the disclosure to the specific embodiments, and it is to be understood as embracing all included in the spirit and scope of the present disclosure changes, equivalents, and substitutes.

Like reference numerals are used for like constituent elements in describing each drawing. In the accompanying drawings, the dimensions of the structure are exaggerated and shown for clarity of the present disclosure. Terms such as first, second, and the like will be used only to describe various constituent elements, and are not to be interpreted as limiting these constituent elements. The terms are only used to differentiate one constituent element from other constituent elements. For example, a first constituent element could be termed a second constituent element, and similarly, a second constituent element could be termed as a first constituent element, without departing from the scope of the present disclosure.

In the present application, it should be understood that the term “include”, “comprise”, “have”, or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations, in advance. It will be understood that when an element such as a layer, film, region, area, or substrate is referred to as being “on” another element, it can be directly on the other element or intervening elements may also be present. In addition, in the present specification, when an element of a layer, film, region, area, plate, or the like is referred to as being formed “on” another element, the formed direction is not limited to an upper direction but includes a lateral or lower direction. In contrast, when an element of a layer, film, region, area, plate, or the like is referred to as being “below” another element, it may be directly below the other element, or intervening elements may be present.

It is to be understood that, in the present application, when it is described for one constituent element (for example, a first constituent element) to be (functionally or communicatively) “coupled or connected with/to” another constituent element (for example, a second constituent element), the one constituent element may be directly coupled or connected with/to the another constituent element, or may be coupled or connected with/to through the other constituent element (for example, a third constituent element). In contrast, it is to be understood that when it is described for one constituent element (for example, a first constituent element) to be “directly coupled or connected with/to” another constituent element (for example, a second constituent element), there is no other constituent element (for example, a third constituent element) between the one constituent element and the another constituent element.

Hereinafter, with reference to accompanying drawings, aspects of some embodiments of the present disclosure and others required for those skilled in the art to understand the contents of the present disclosure will be described in more detail. In the description below, singular forms are to include plural forms unless the context clearly indicates only the singular.

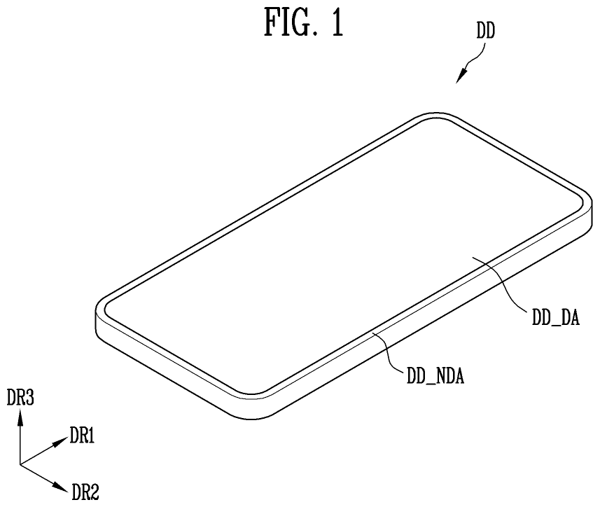

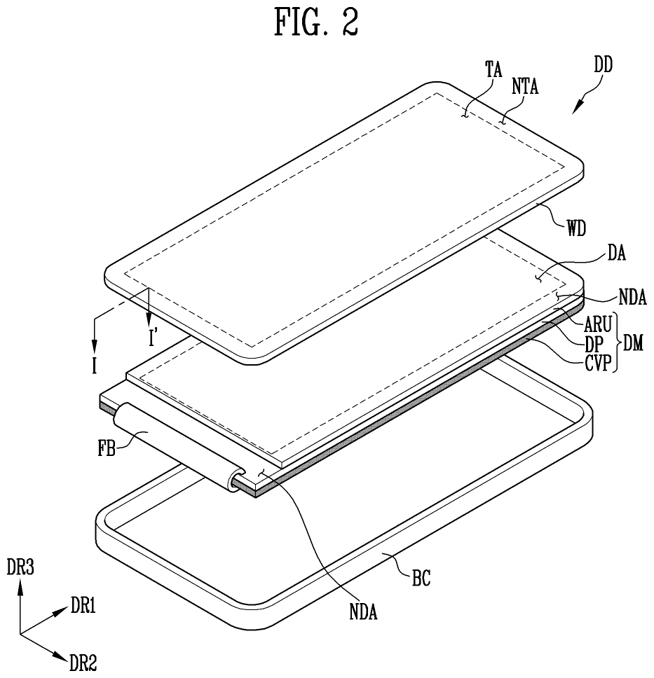

FIG. 1 illustrates a schematic perspective view of a display device DD according to one or more embodiments, and FIG. 2 illustrates a schematic exploded perspective view of the display device DD according to the embodiments.

The display device DD may include at least one of electronic devices having a display surface applied to at least one surface thereof, such as a smart phone, a television, a tablet PC, a mobile phone, an image phone, an electron book reader, a desktop PC, a laptop PC, a netbook computer, a workstation, a server, a PDA, a portable multimedia player (PMP), an MP3 player, a medical device, a camera, or a wearable device.

Referring to FIG. 1 and FIG. 2, the display device DD according to the embodiments may be provided in various shapes, for example, may be provided in a rectangular plate shape having two pairs of sides parallel to each other, but is not limited thereto. When the display device DD is provided in the rectangular plate shape, sides of one pair of the two pairs of sides may be provided to be longer than sides of the other pair thereof.

In FIG. 1 and FIG. 2, for better understanding and ease of description, a case in which the display device DD has a rectangular shape having a pair of long sides and a pair of short sides is illustrated, and an extending direction of the long side is indicated as a first direction DR1, an extending direction of the short side is indicated as a second direction DR2, and a thickness direction of the display device DD is indicated as a third direction DR3.

At least a portion of the display device DD may have flexibility, and may be folded at a portion having the flexibility.

The display device DD may include a display area DD_DA for displaying an image and a non-display area DD_NDA provided in at least one side of the display area DD_DA. The non-display area DD_NDA is an area in which an image is not displayed. However, the present disclosure is not limited thereto, and in some embodiments, the shape of the display area DD_DA and the shape of the non-display area DD_NDA may be relatively designed.

In some embodiments, the display device DD may include a sensing area and a non-sensing area. The display device DD not only may display an image through the sensing area, but also may detect a touch input made on a display surface (or input surface) or may detect light incident from the front. The non-sensing area may surround the sensing area, but this is merely an illustration, and embodiments according to the present disclosure are not limited thereto. In some embodiments, a partial area of the display area DD_DA may correspond to the sensing area.

The display device DD may include a window WD and a display module DM.

The window WD may be located on the display module DM to protect the display module DM from external impact, and transmit an image provided from the display module DM to a transmissive area TA. The window WD may include the transmissive area TA and a non-transmissive area NTA.

The transmissive area TA may have a shape corresponding to the display area DD_DA of the display device DD. For example, an image displayed in the display area DD_DA of the display device DD may be viewed from the outside through the transmissive area TA of the window WD.

The non-transmissive area NTA may have a shape corresponding to the non-display area DD_NDA of the display device DD. The non-transmissive area NTA may be an area having relatively low light transmittance compared to the transmissive area TA. However, the present disclosure is not limited thereto, and the non-transmissive area NTA may be omitted.

The window WD may have a suitable (or selected) multi-layered structure from a glass substrate, a plastic film, a plastic substrate. Such a multi-layered structure may be formed through a continuous process or an adhesive process using an adhesive layer. The window WD may be entirely or partially flexible.

The display module DM may be located between the window WD and a receiving member BC.

The display module DM may include a display panel DP, an optical layer ARU, a circuit board FB, and a cover panel CVP.

The display panel DP may display an image. As the display panel DP, a self-light emitting display panel such as an organic light emitting display panel (OLED panel) using an organic light emitting diode as a light emitting element, a nano-scale LED display panel using an ultra small light emitting diode as a light emitting element, or a quantum dot organic light emitting display panel (QD OLED panel) using a quantum dot and an organic light emitting diode may be used. In addition, as the display panel DP, a non-light emitting display panel such as a liquid crystal display panel (LCD panel), an electro-phoretic display panel (EPD panel), or an electro-wetting display panel (EWD panel) may be used. When a non-light emitting display panel is used as the display panel DP, the display device DD may include a backlight unit that supplies light to the display panel DP.

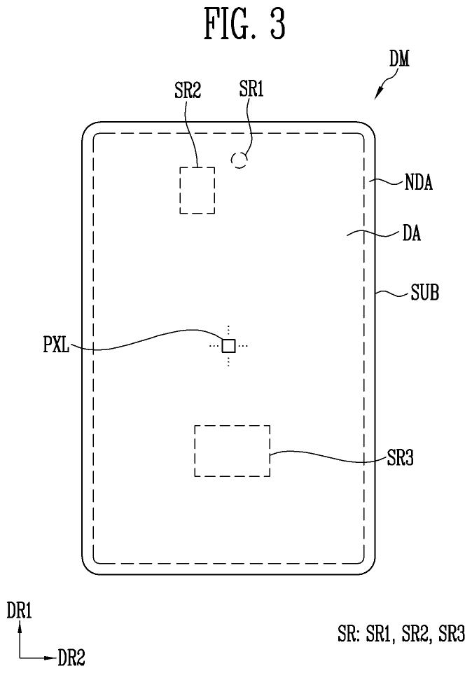

The display panel DP may include a display area DA and a non-display area NDA. The display area DA may be an area in which a plurality of pixels (refer to “PXL” in FIG. 3) are provided to display an image, and the non-display area NDA may be an area in which the pixels PXL are not provided and no image is displayed. The display area DA may correspond to the display area DD_DA of the display device DD, and the non-display area NDA may correspond to the non-display area DD_NDA of the display device DD.

A touch sensor may be located between the display panel DP and the window WD. The touch sensor may be directly located on a surface of the display panel DP on which an image is displayed to receive a user's touch input.

The optical layer ARU may be positioned on the display panel DP. The optical layer ARU may reduce external light reflection. The optical layer ARU may be, for example, an anti-reflection layer including a polarizing film and/or a retardation film. The number of the retardation films and a retardation length (λ/4 or λ/2) of the retardation film may be determined according to an operation principle of the optical layer ARU. In some embodiments, the optical layer ARU may include color filters.

The circuit board FB may be connected (or attached) to one end (or one side) of the display panel DP to provide a driving signal and voltage to the display panel DP. For example, the driving signal may be a signal for displaying an image on the display panel DP, and the voltage may be a driving voltage required for driving the display panel DP. The circuit board FB may be provided as a flexible printed circuit board. The circuit board FB may be folded along one side of an upper surface (or a first surface) of the display panel DP as shown in FIG. 2 to be positioned on a rear surface (or a second surface) of the display panel DP.

In addition, the circuit board FB may process various signals inputted from a printed circuit board to output them to the display panel DP. To this end, the circuit board FB may be respectively attached to the display panel DP and the printed circuit board to be electrically connected to the display panel DP and the printed circuit board, respectively.

The cover panel CVP may be provided on a rear surface of the display module DM, that is, on a surface on which no image is displayed. The cover panel CVP may protect the display module DM from external impact and the like. The cover panel CVP may be made of a high-viscosity material, for example, a curable resin. A more detailed description of the cover panel CVP will be described later.

The receiving member BC may be combined with the window WD. The receiving member BC provides a rear surface of the display device DD, and may be combined with the window WD to define an internal space. The receiving member BC may include a material having a relatively high rigidity. For example, the receiving member BC may include a plurality of frames and/or plates made of glass, plastic, and metal. The receiving member BC may stably protect components of the display device DD accommodated in the internal space from external impact. In addition, it is described that the receiving member BC includes a material having high rigidity, but the present disclosure is not limited thereto, and the receiving member BC may include a flexible material. According to some embodiments, the display device DD may have a characteristic that may be folded or bent. As a result, the components included in the display device DD may also have flexible properties.

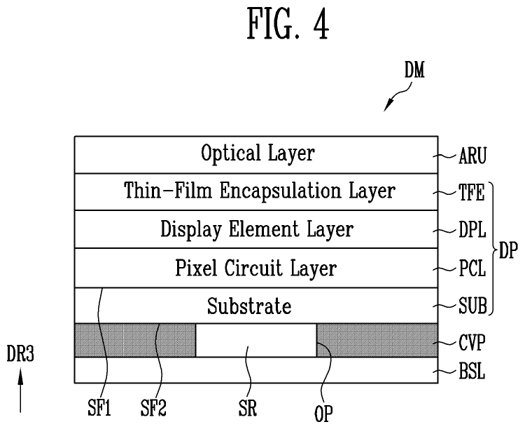

FIG. 3 illustrates a schematic top plan view of a display module DM according to one or more embodiments, and FIG. 4 illustrates a schematic cross-sectional view of the display module DM of FIG. 3.

Referring to FIG. 1 to FIG. 4, the display module DM according to the embodiments may include the display panel DP, the optical layer ARU, the cover panel CVP, a base layer BSL, and a sensor SR.

The display panel DP may include a substrate SUB, a pixel circuit layer PCL, a display element layer DPL, and a thin film encapsulation layer TFE.

The substrate SUB may include a transparent insulating material to transmit light. The substrate SUB may be a rigid substrate or a flexible substrate.

For example, the rigid substrate may be one of a glass substrate, a quartz substrate, a glass ceramic substrate, and a crystalline glass substrate.

The flexible substrate may be one of a film substrate and a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate.

The substrate SUB may include the display area DA and the non-display area NDA. The display area DA may be an area in which the pixels PXL are provided to display an image, and the non-display area NDA may be an area in which the pixels PXL are not provided and no image is displayed.

The substrate SUB may include a first surface SF1 (for example, an upper surface) and a second surface SF2 (for example, a rear surface) facing each other in the third direction DR3.

The pixels PXL may be provided in the display area DA on the substrate SUB (or the display panel DP), and may be electrically connected to signal wires. Each of the pixels PXL may include a plurality of sub-pixels as a minimum unit for displaying an image.

The pixels PXL may include a light emitting element emitting white light and/or color light and a pixel circuit for driving the light emitting element. The pixel circuit may include at least one transistor electrically connected to the light emitting element. Each pixel PXL may emit light of one of red, green and blue colors, but is not limited thereto. Each pixel PXL may emit light of one of cyan, magenta, yellow and white colors.

A plurality of pixels PXL may be provided to be arranged in a matrix form along a row extending in the second direction DR2 and a column extending in the first direction DR1 crossing the second direction DR2. The arrangement form of the pixels PXL is not particularly limited, and the pixels PXL may be arranged in various forms.

The pixel circuit layer PCL may be provided on the first surface SF1 of the substrate SUB, and may include a plurality of transistors and signal wires electrically connected to the transistors. For example, each transistor may have a structure in which a semiconductor layer, a gate electrode, a first terminal, and a second terminal are sequentially stacked with an insulating layer interposed therebetween. The semiconductor layer may include an amorphous silicon, a poly silicon, a low temperature poly silicon, and an organic semiconductor. The gate electrode, the first terminal, and the second terminal may include one of aluminum (Al), copper (Cu), titanium (Ti), and molybdenum (Mo), but are not limited thereto. In addition, the pixel circuit layer PCL may include at least one or more insulating layers.

The display element layer DPL may be located on the pixel circuit layer PCL. The display element layer DPL may include a light emitting element that emits light. The light emitting element may be, for example, an organic light emitting diode, but is not limited thereto. In some embodiments, the light emitting element may be an inorganic light emitting element including an inorganic light emitting material or a light emitting element that emits light by changing a wavelength of light emitted by using a quantum dot.

The thin film encapsulation layer TFE may be located on the display element layer DPL. The thin film encapsulation layer TFE may be an encapsulation substrate or a multi-layered encapsulation film. When the thin film encapsulation layer TFE is in a form of the encapsulation film, it may include an inorganic film and/or an organic film. For example, the thin film encapsulation layer TFE may have a structure in which an inorganic film, an organic film, and an inorganic film are sequentially stacked. The thin film encapsulation layer TFE may prevent external air and moisture from penetrating into the display element layer DPL and the pixel circuit layer PCL.

The optical layer ARU is located on the thin film encapsulation layer TFE, and may reduce external light reflection.

The cover panel CVP may be located on the second surface SF2 of the substrate SUB, for example, on a surface on which no image is displayed. The cover panel CVP may include at least one opening OP to expose one area of the second surface SF2 of the substrate SUB.

The sensor SR may be an optical component that is inserted (or mounted) in the opening OP of the cover panel CVP to overlap at least a portion of the display area DA. The sensor SR may include a component that may receive light or may emit light. The sensor SR may be located under the pixels PXL and/or signal wires that are located in the display area DA to be hidden from the front surface of the display device DD. When the sensor SR is arranged to overlap a lower portion of the display area DA, the appearance of the display device DD, in particular, the appearance of the front surface corresponding to the display area DA, becomes beautiful, and the wider display area DA may be obtained.

The sensor SR may include, for example, a fingerprint sensor, an image sensor, a camera, a strobe, an optical sensor, an illuminance sensor, a proximity sensor, an RGB sensor, an infrared sensor (or a motion sensor), an indicator, and a solar panel. However, the sensor SR is not limited to an optical element, and it may include various elements such as an ultrasonic sensor, a microphone, an environmental sensor (for example, a barometer, a hygrometer, a thermometer, a radiation sensor, a thermal sensor, etc.), and a chemical sensor (for example, a gas detection sensor, a dust detection sensor, a odor detection sensor, etc.). The sensor SR may include, for example, a first sensor SR1, a second sensor SR2, and a third sensor SR3. The first sensor SR1 may be a camera, the second sensor SR2 may be an infrared sensor, and the third sensor SR3 may be a fingerprint sensor.

The above-described sensor SR may be located on a separate base layer BSL made of a plastic or metal material such as a bracket, a case, and the like to face (or correspond to) at least one area of the display area DA in a surface mount device (SMD) method.

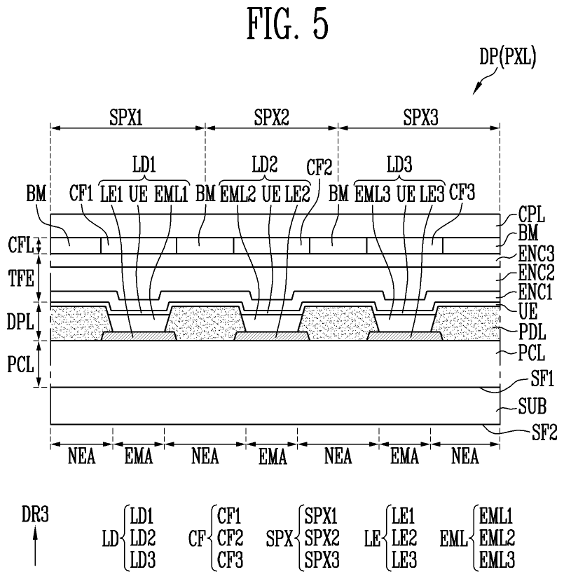

FIG. 5 illustrates a schematic cross-sectional view of a display panel DP according to one or more embodiments.

In FIG. 5, for better comprehension and ease of description, a structure of the display panel DP is simply illustrated based on the pixel PXL provided on the substrate SUB, and a thickness direction of the substrate SUB is indicated by the third direction DR3.

Referring to FIG. 1 to FIG. 5, the display panel DP may include at least one or more pixels PXL provided on the substrate SUB.

The pixel PXL may be located at a pixel area included in the display area DA. In the embodiments, the display area DA may include a light emitting area EMA and a non-light emitting area NEA adjacent to the light emitting area EMA.

The pixel PXL may include a plurality of sub-pixels SPX. For example, the PXL may include a first sub-pixel SPX1, a second sub-pixel SPX2, and a third sub-pixel SPX3.

Each of the first, second, and third sub-pixels SPX1, SPX2, and SPX3 may include the pixel circuit layer PCL, the display element layer DPL, and the thin film encapsulation layer TFE sequentially arranged on the first surface SF1 of the substrate SUB.

The pixel circuit layer PCL may include a pixel circuit provided on the first surface SF1 of the substrate SUB and signal wires electrically connected to the pixel circuit. In addition, the pixel circuit layer PCL may include at least one or more insulating layers positioned between components included in the pixel circuit.

The display element layer DPL may be positioned on the pixel circuit layer PCL. The display element layer DPL may include the light emitting element LD that emits light. The light emitting element LD may include a first electrode LE (or a lower electrode), a light emitting layer EML, and a second electrode UE (or an upper electrode). The first electrode LE may be an anode, and the second electrode UE may be a cathode. The second electrode UE may be a common layer commonly provided to adjacent pixels PXL.

In the embodiments, the first electrode LE may include a (1-1)-th electrode LE1, a (1-2)-th electrode LE2, and a (1-3)-th electrode LE3. The (1-1)-th electrode LE1 may be positioned at the first sub-pixel SPX1, the (1-2)-th electrode LE2 may be positioned at the second sub-pixel SPX2, and the (1-3)-th electrode LE3 may be positioned at the third sub-pixel SPX3.

The light emitting layer EML includes a first light emitting layer EML1 positioned on the (1-1)-th electrode LE1, a second light emitting layer EML2 positioned on the (1-2)-th electrode LE2, and a third light emitting layer EML3 positioned on the (1-3)-th electrode LE3. The first light emitting layer EML1, the second light emitting layer EML2, and the third light emitting layer EML3 may emit different light. For example, the first light emitting layer EML1 may emit red light, the second light emitting layer EML2 may emit green light, and the third light emitting layer EML3 may emit blue light. In this case, the first sub-pixel SPX1 may be a red pixel (or a red sub-pixel), the second sub-pixel SPX2 may be a green pixel (or a green sub-pixel), and the third sub-pixel SPX3 may be a blue pixel (or a blue sub-pixel). Each of the first, second, and third light emitting layers EML1, EML2, and EML3 may include a light generating layer emitting light, an electron transporting layer, and a hole transporting layer.

The (1-1)-th electrode LE1, the first light emitting layer EML1, and the second electrode UE may configure a first light emitting element LD1. The first light emitting element LD1 may be positioned in the first sub-pixel SPX1.

The (1-2)-th electrode LE2, the second light emitting layer EML2, and the second electrode UE may configure a second light emitting element LD2. The second light emitting element LD2 may be positioned in the second sub-pixel SPX2.

The (1-3)-th electrode LE3, the third light emitting layer EML3, and the second electrode UE may configure a third light emitting element LD3. The third light emitting element LD3 may be positioned in the third sub-pixel SPX3.

A pixel defining film PDL may be positioned on the first electrode LE. The pixel defining film PDL may be partially opened to expose one area of the (1-1)-th electrode LE1, one area of the (1-2)-th electrode LE2, and one area of the (1-3)-th electrode LE3, respectively. The pixel defining film PDL may be a structure defining (or partitioning) the light emitting area EMA of each of the first, second, and third sub-pixels SPX1, SPX2, and SPX3.

The second electrode UE may be positioned on the first, second, and third light emitting layers EML1, EML2, and EML3 and the pixel defining film PDL. The second electrode UE is a transmissive electrode, and may include a transparent conductive material.

The thin film encapsulation layer TFE may be positioned on the second electrode UE.

The thin film encapsulation layer TFE may be formed as a single film, and it may be formed as a multi-film. The thin film encapsulation layer TFE may include a plurality of insulating films covering the first, second, and third light emitting elements LD1, LD2, and LD3. Specifically, the thin film encapsulation layer TFE may include at least one inorganic film and at least one organic film. For example, the thin film encapsulation layer TFE may have a structure in which an inorganic film and an organic film are alternately stacked. In the embodiments, the thin film encapsulation layer TFE may be an encapsulation substrate that may be located on the first, second, and third light emitting elements LD1, LD2, and LD3 and may be bonded to the substrate SUB through a sealant.

The thin film encapsulation layer TFE may include first, second, and third encapsulation layers ENC1, ENC2, and ENC3 sequentially positioned on the second electrode UE. The first encapsulation layer ENC1 may be positioned on the display element layer DPL to be positioned in at least a portion of the display area DA and the non-display area NDA. The second encapsulation layer ENC2 may be positioned on the first encapsulation layer ENC1 to be positioned in at least a portion of the display area DA and the non-display area NDA. The third encapsulation layer ENC3 may be positioned on the second encapsulation layer ENC2 to be positioned in at least a portion of the display area DA and the non-display area NDA. In some embodiments, the third encapsulation layer ENC3 may be arranged to entirely overlap the display area DA and the non-display area NDA.

Each of the first and third encapsulation layers ENC1 and ENC3 may be formed of an inorganic film including an inorganic material, and the second encapsulation layer ENC2 may be formed of an organic film including an organic material. The material of the inorganic film is, for example, a silicon nitride (SiNₓ), a silicon oxide (SiOₓ), or a silicon oxynitride (SiOₓN_{y}), and the like. The organic film may include an organic insulating material such as a polyacrylates resin, an epoxy resin, a phenolicresin, a polyamides resin, a polyimides rein, an unsaturated polyesters resin, a poly phenylenethers resin, a polyphenylenesulfides resin, or benzocyclobutene (BCB).

A color filter layer CFL may be selectively arranged on the thin film encapsulation layer TFE. The color filter layer CFL may include a color filter CF and a light blocking pattern BM.

The light blocking pattern BM may be positioned to correspond to the pixel defining film PDL on one surface of the thin film encapsulation layer TFE. The light blocking pattern BM may include a light blocking material. For example, the light blocking pattern BM may be a black matrix. In some embodiments, the light blocking pattern BM may be configured to include at least one light blocking material and/or reflective material, so that light emitted from the light emitting layer EML may further proceed in an image display direction of the display device DD to improve light output efficiency.

The color filter CF may be positioned on the corresponding light emitting layer EML in the light emitting area EMA surrounded by the pixel defining film PDL. The color filter CF may include a first color filter CF1 positioned on the first light emitting layer EML1, a second color filter CF2 positioned on the second light emitting layer EML2, and a third color filter CF3 positioned on the third light emitting layer EML3.

Each of the first, second, and third color filters CF1, CF2, and CF3 may include a colorant such as a dye or a pigment that absorbs light of a wavelength other than the corresponding color wavelength. The first color filter CF1 may be a red color filter, the second color filter CF2 may be a green color filter, and the third color filter CF3 may be a blue color filter. In the drawing, the case in which the adjacent color filters CF are arranged to be spaced apart from each other with the light blocking pattern BM interposed therebetween, the adjacent color filters CF may at least partially overlap each other on the light blocking pattern BM.

In some embodiments, between the color filter layer CFL and the thin film encapsulation layer TFE, a color converting layer including color converting particles (for example, quantum dots) that convert light of a first color emitted from the light emitting elements LD into light of a second color (or light of a specific color) different from light of the first color may be provided.

A capping layer CPL may be located on the color filter layer CFL. The capping layer CPL may prevent impurities such as moisture or air from penetrating from the outside to damage or contaminate the color filter layer CFL. In addition, the capping layer CPL may prevent a colorant of the color filter layer CFL from being diffused into other components. The capping layer CPL may be an inorganic film including an inorganic material.

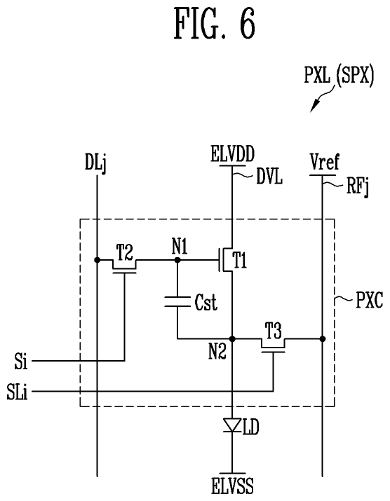

FIG. 6 illustrates a schematic circuit diagram of an electrical connection relationship of constituent elements included in each of the pixels PXL illustrated in FIG. 3.

For example, FIG. 6 illustrates an electrical connection relationship between constituent elements included in the pixel PXL applicable to an active matrix type of a display device DD according to one or more embodiments. However, the connection relationship between the constituent elements of each pixel PXL is not limited thereto.

Referring to FIG. 1 to FIG. 6, the pixel PXL (or sub-pixel SPX) may include the light emitting element LD and a pixel circuit PXC electrically connected to the light emitting element LD to drive the light emitting element LD.

A first electrode of the light emitting element LD may be electrically connected to the pixel circuit PXC. The light emitting element LD emits light of a luminance (e.g., a set or predetermined luminance) in response to an amount of current supplied from the pixel circuit PXC. For this purpose, during a driving period of the display device DD, a second driving power source ELVSS may be set to a lower voltage than that of a first driving power source ELVDD, but is not limited thereto.

When the pixel PXL (or sub-pixel SPX) is positioned in an i-th row and a j-th column in the display area DA, the pixel circuit PXC of the pixel PXL (or sub-pixel SPX) may be electrically connected to an i-th scan line Si and a j-th data line DLj. In addition, the pixel circuit PXC may be electrically connected to an i-th sensing line SLi and a j-th reference voltage line RFj.

The pixel circuit PXC may control an amount of current flowing from the first driving power source ELVDD to the second driving power source ELVSS via the light emitting element LD in response to a data signal (or a data voltage).

The pixel circuit PXC may include a first transistor T1, a second transistor T2, a third transistor T3, and a storage capacitor Cst.

The first transistor T1 is a driving transistor for controlling a driving current applied to the light emitting element LD, and may be electrically connected between the first driving power source ELVDD and the light emitting element LD. Specifically, a first terminal of the first transistor T1 may be electrically connected to the first driving power source ELVDD through a driving voltage wire DVL, a second terminal of the first transistor T1 may be electrically connected to a second node N2, and a gate electrode of the first transistor T1 may be electrically connected to a first node N1. The first transistor T1 may control an amount of the driving current applied to the light emitting element LD from the first driving power source ELVDD through the second node N2 according to a voltage applied to the first node N1. In the embodiments, the first terminal of the first transistor T1 may be a drain electrode, and the second terminal of the first transistor T1 may be a source electrode, but the present disclosure is not limited thereto. In some embodiments, the first terminal thereof may be a source electrode, and the second terminal thereof may be a drain electrode.

The second transistor T2 is a switching transistor that selects the pixel PXL in response to a scan signal and activates the pixel PXL, and may be electrically connected between the j-th data line DLj and the first node N1. A first terminal of the second transistor T2 may be electrically connected to the j-th data line DLj, a second terminal of the second transistor T2 may be electrically connected to the first node N1, and a gate electrode of the second transistor T2 may be electrically connected to the i-th scan line Si. The first terminal and the second terminal of the second transistor T2 are different terminals, and for example, when the first terminal is a drain electrode, the second terminal may be a source electrode, but is not limited thereto. In some embodiments, the first terminal thereof may be a source electrode, and the second terminal thereof may be a drain electrode.

When a scan signal of a gate-on voltage (for example, a high level voltage) is supplied from the i-th scan line Si, the second transistor T2 described above may be turned on to electrically connect the j-th data line DLj and the first node N1. The first node N1 may be a point at which the second terminal of the second transistor T2 and the gate electrode of the first transistor T1 are electrically connected. The second transistor T2 may transmit a data signal to the gate electrode of the first transistor T1.

The third transistor T3 is turned on when a sensing signal is supplied from the i-th sensing line SLi to be able to electrically connect the j-th reference voltage line RFj to the first transistor T1 (or second node N2). A first terminal of the third transistor T3 may be electrically connected to the j-th reference voltage line RFj, the second terminal of the third transistor T3 may be electrically connected to the second node N2, and the gate electrode of the third transistor T3 may be electrically connected to the i-th sensing line SLi.

The third transistor T3 may be a sensing transistor operable to supply a reference voltage Vref transmitted through the j-th reference voltage line RFj to the second node N2 or to sense the reference voltage Vref or current of the second node N2 or the j-th reference voltage line RFj. Here, the reference voltage Vref may be a voltage lower than a voltage of the first driving power source ELVDD and/or the data voltage, for example, a voltage of the initialization power source.

The storage capacitor Cst may include a first storage electrode and a second storage electrode. The first storage electrode of the storage capacitor Cst may be electrically connected to the first node N1, and the second storage electrode of the storage capacitor Cst may be electrically connected to the second node N2. The storage capacitor Cst may be charged with a voltage corresponding to the data signal supplied to the first node N1 during one frame period. The storage capacitor Cst may store a voltage corresponding to a difference between a voltage of the gate electrode of the first transistor T1 and a voltage of the second node N2.

In FIG. 6, the embodiments in which the first, second, and third transistors T1, T2, and T3 included in the pixel circuit PXC are all N-type transistors is illustrated, but is not limited thereto. For example, at least one of the first, second, or third transistors T1, T2, or T3 may be changed to a P-type transistor or an oxide transistor.

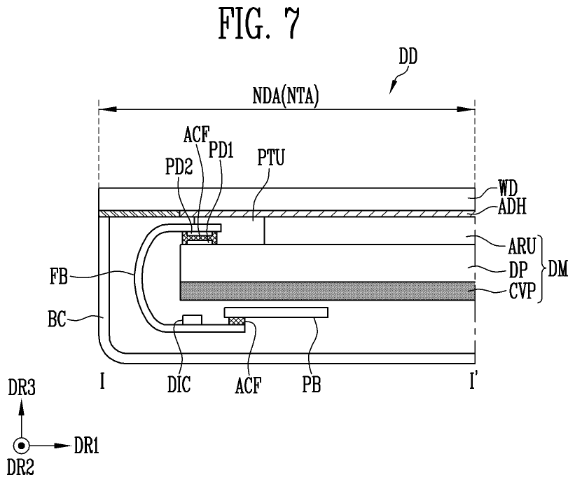

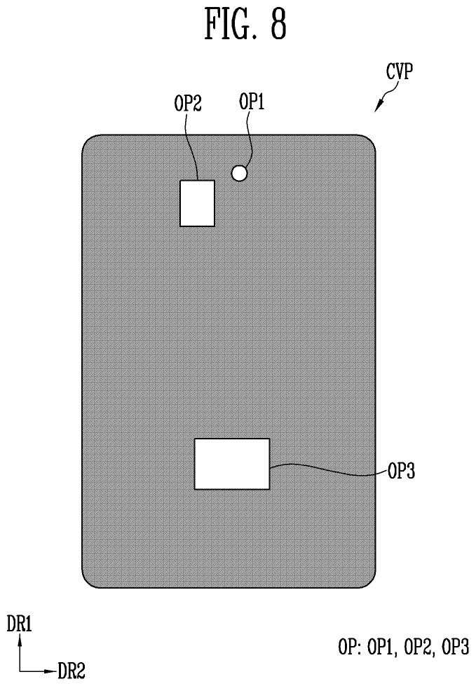

FIG. 7 illustrates a schematic cross-sectional view taken along line I-I′ of FIG. 2, and FIG. 8 illustrates a schematic top plan view of a cover panel CVP of FIG. 7.

In relation to the embodiments of FIG. 7 and. 8, differences from the above-described embodiments will be mainly described in order to avoid duplicate descriptions.

Referring to FIG. 1 to FIG. 8, the display device DD may include the display module DM, the window WD, and the receiving member BC.

The display module DM may include the display panel DP, the optical layer ARU, the circuit board FB, a printed circuit board PB, a protective member PTU, and the cover panel CVP. The window WD may be attached to the optical layer ARU through an adhesive member ADH.

The display panel DP may include the substrate SUB, the pixels PXL provided on the first surface SF1 of the substrate SUB, and the thin film encapsulation layer TFE provided on the pixels PXL. In addition, the display panel DP may include a first pad PD1 positioned in the non-display area NDA.

The optical layer ARU may be provided on the display panel DP.

The circuit board FB may be located on one side of the display panel DP so that one surface on which a second pad PD2 is positioned faces the first pad PD1. The second pad PD2 of the circuit board FB may be electrically connected to the first pad PD1 of the display panel DP through a conductive adhesive member ACF. The circuit board FB may be folded along one side of the display module DM to be positioned on the rear surface of the display module DM.

The circuit board FB may be electrically connected to the printed circuit board PB. The printed circuit board PB and the circuit board FB may be attached to each other through the conductive adhesive member ACF. A driver DIC may be positioned on the circuit board FB.

The driver DIC may receive the driving signals outputted from the printed circuit board PB, and may output a signal (e.g., a set or predetermined signal) and a driving voltage (e.g., a set or predetermined driving voltage) (or a driving power source) to be provided to the pixels PXL based on the received driving signals. The above-described signals (e.g., a set or predetermined signals) and driving voltage (e.g., a set or predetermined driving voltage) may be transmitted to the first pad PD1 on the display panel DP through the second pad PD2 on the circuit board FB.

In the above embodiments, it has been described that the driver DIC is located on the circuit board FB, but the present disclosure is not limited thereto, and in some embodiments, the driver DIC may be located (or mounted) on the substrate SUB of the display panel DP.

The printed circuit board PB may generate overall driving signals and power signals necessary for driving the display panel DP to provide them to the display panel DP. The printed circuit board PB may include a pad. The pad may be electrically connected to the second pad PD2 of the circuit board FB. As a result, the driving signals and the power signals may be transmitted from the printed circuit board PB to the driver DIC through the circuit board FB.

The protective member PTU may be partially positioned on the circuit board FB attached to one side surface of the display panel DP to correspond to a bonding portion between the circuit board FB and the display panel DP.

The protective member PTU may be located on one side surface of each of the circuit board FB and the display panel DP and cover the bonding portion between the circuit board FB and the display panel DP. The protective member PTU may protect the bonding portion, and may block external moisture and the like from flowing into the bonding portion and proceeding to the pixels PXL of the display panel DP. In the embodiments, the bonding portion of the circuit board FB and the display panel DP may be a position at which the second pad PD2 of the circuit board FB and the first pad PD1 of the display panel DP are coupled to each other through the conductive adhesive member ACF.

The cover panel CVP may be directly located on the rear surface of the display panel DP (for example, the second surface SF2 of the substrate SUB) to protect the rear surface of the display panel DP. The cover panel CVP may include a material with a high impact absorption rate and/or a material with a good heat dissipation characteristic. In addition, the cover panel CVP may include a material having an electromagnetic wave shield or absorption characteristic.

In the embodiments, the cover panel CVP may include a curable resin that has adhesive properties and is cured by heat or light. For example, the curable resin may be made of a thermosetting resin, and may include a bisphenol A-type epoxy resin, a bisphenol F-type epoxy resin, a novolak-type epoxy resin, a phenol resin, a urea resin, a melamine resin, an unsaturated polyester resin, a resorcinol resin, and the like, but is not limited thereto. As another example, the curable resin may include a photocurable resin including a photopolymerization initiator that is cured by light such as UV. In some embodiments, the cover panel CVP may include a thermosetting resin or a light-curing resin including a light blocking material. The cover panel CVP may include a resin based on epoxy, acryl, urethane, and the like including black particles. The light blocking material may include, for example, a material based on a carbon black, a titanium black, an iron sulfide, and the like, but is not limited thereto.

The cover panel CVP may include at least one or more opening OP. The opening OP may be an empty space opened by removing at least one area of the cover panel CVP. The opening OP may be a through hole passing through at least one area of the cover panel CVP.

In the embodiments, the opening OP may include a first opening OP1, a second opening OP2, and a third opening OP3 positioned to be spaced apart from each other. The first opening OP1 may expose one area of the second surface SF2 (or the rear surface) of the substrate SUB, the second opening OP2 may expose another area of the second surface SF2 (or the rear surface) of the substrate SUB, and the third opening OP3 may expose yet another area of the second surface SF2 (or the rear surface) of the substrate SUB. The first opening OP1 of the cover panel CVP may be an area in which the first sensor SR1 may be positioned, the second opening OP2 of the cover panel CVP may be an area in which the second sensor SR2 may be positioned, and the third opening OP3 of the cover panel CVP may be an area in which the third sensor SR3 may be positioned. For example, the first sensor SR1 may be inserted (or mounted) in the first opening OP1 of the cover panel CVP to overlap an area of the second surface SF2 (or the rear surface) of the substrate SUB, the second sensor SR2 may be inserted (or mounted) in the second opening OP2 of the cover panel CVP to overlap yet another area of the second surface SF2 (or the rear surface) of the substrate SUB, and the third sensor SR3 may be inserted (or mounted) in the third opening OP3 of the cover panel CVP to overlap another area of the second surface SF2 (or the rear surface) of the substrate SUB.

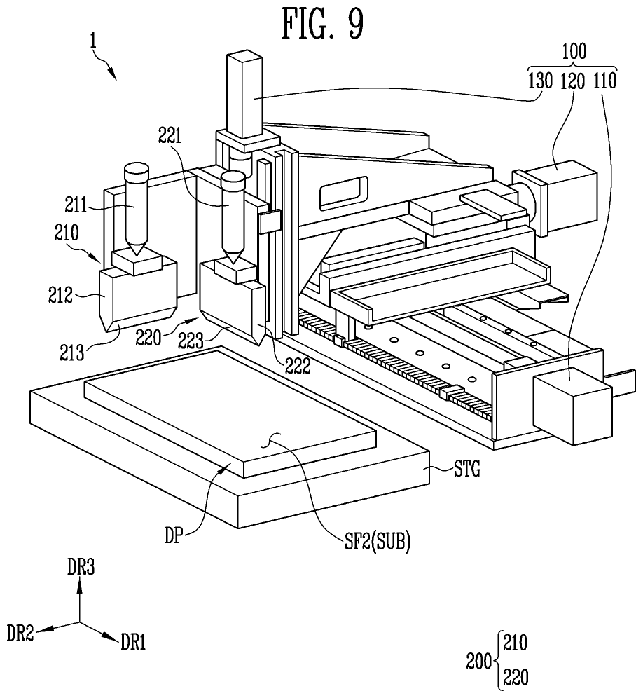

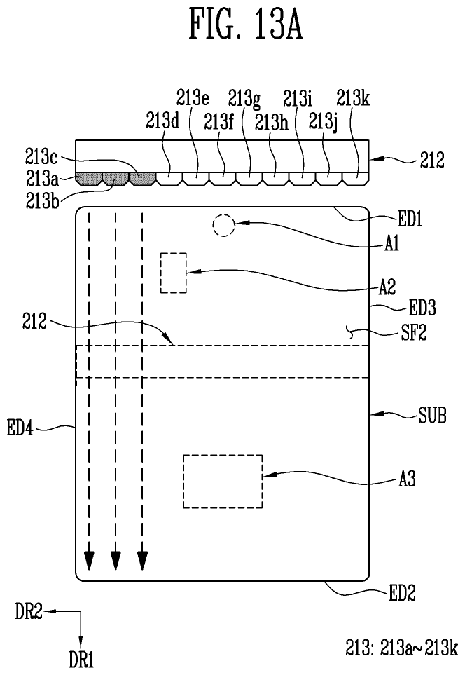

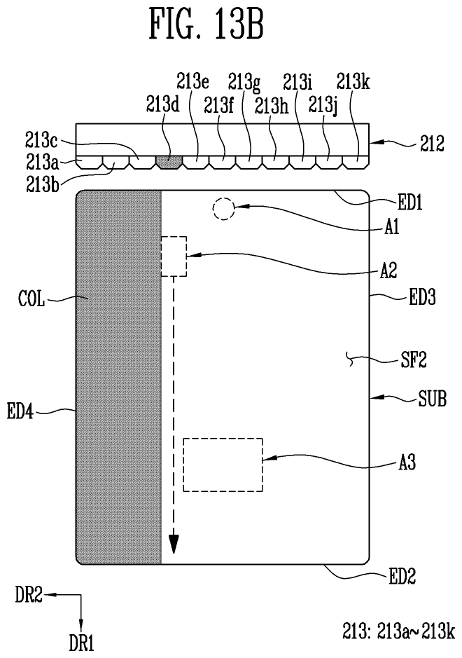

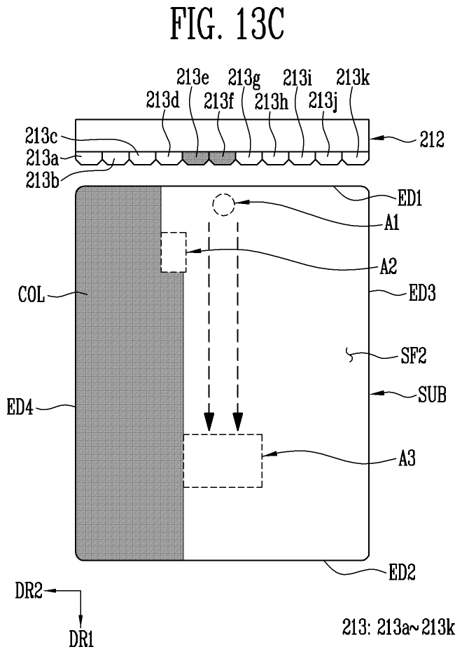

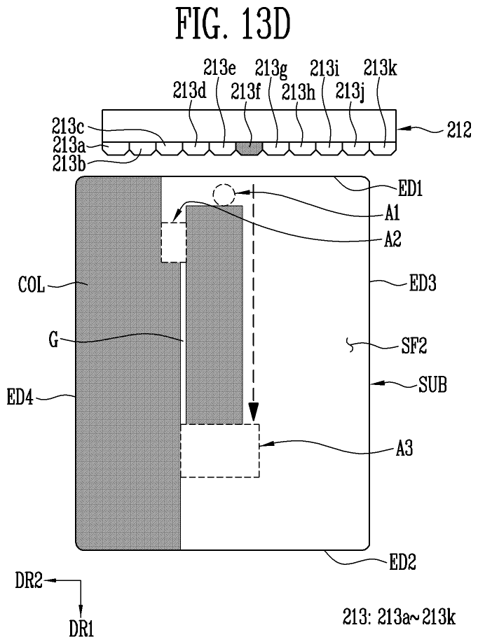

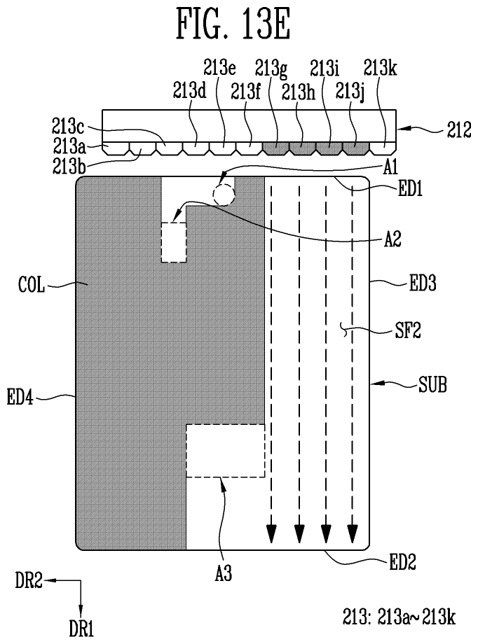

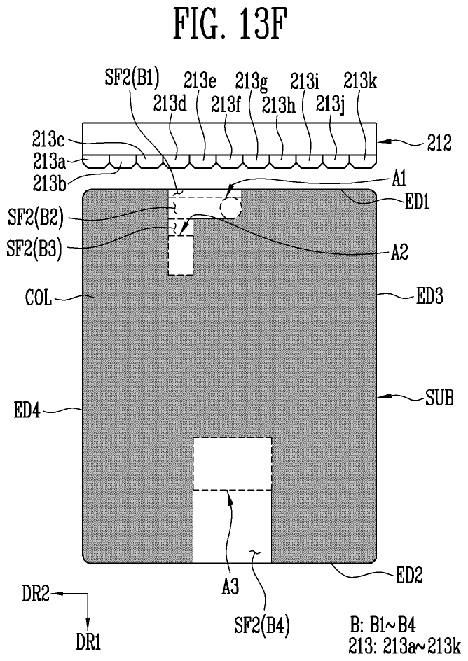

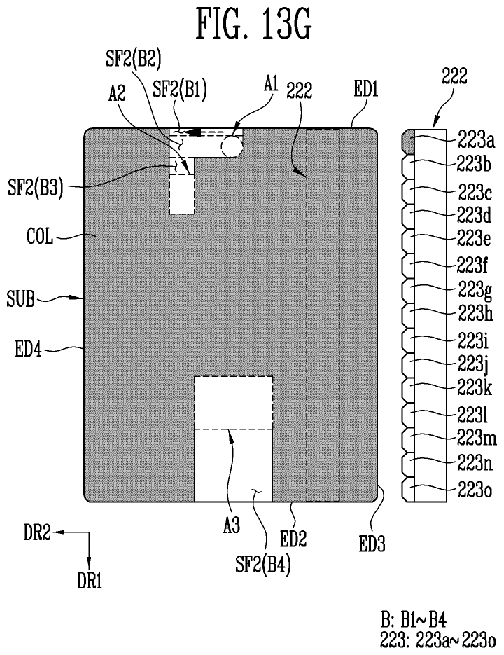

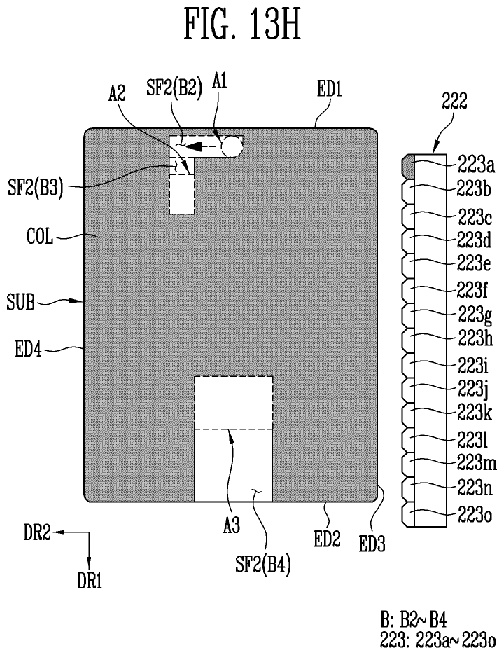

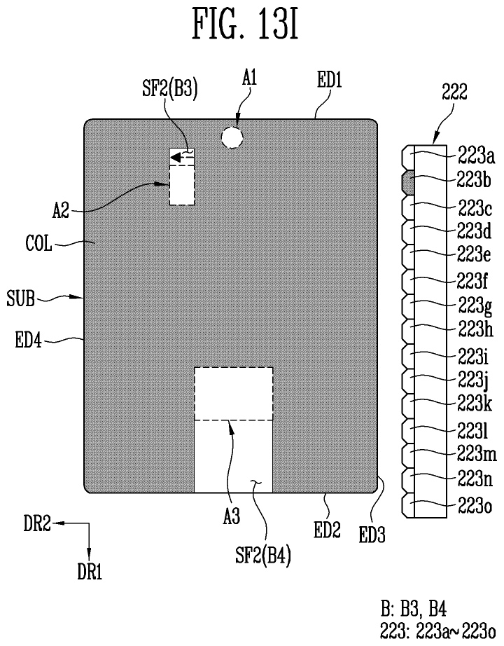

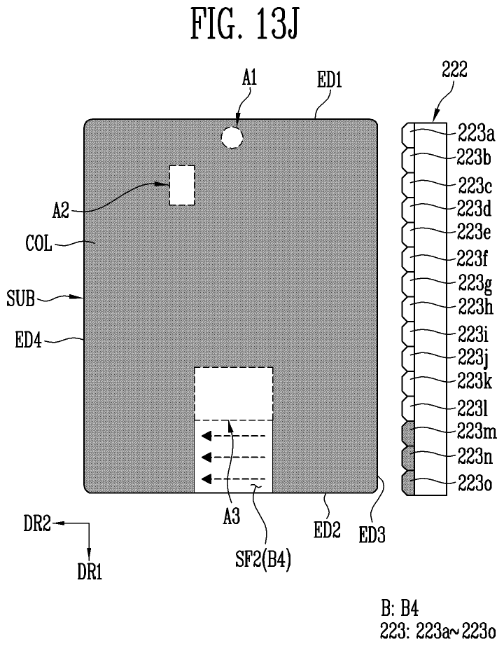

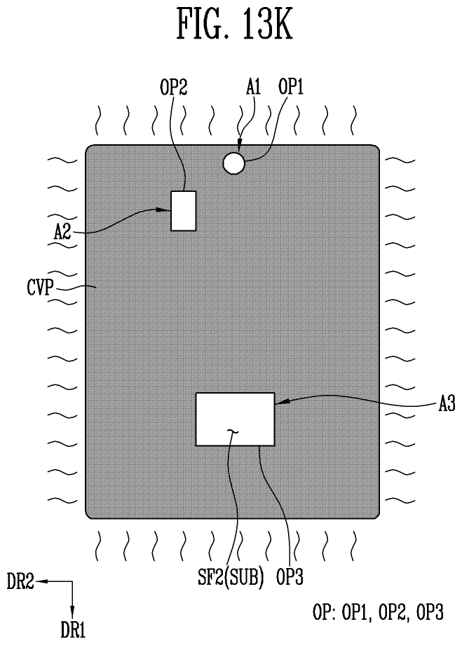

The cover panel CVP described above may be coated on the second surface SF2 (or the rear surface) of the substrate SUB by a coating apparatus (refer to “1” in FIG. 9), and then may be finally formed in a shape including the opening OP by performing a curing process. The manufacturing process of the cover panel CVP will be described later with reference to FIG. 13A to FIG. 13K.

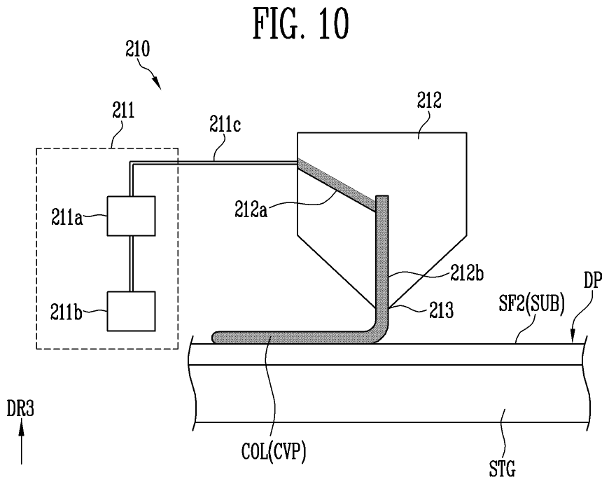

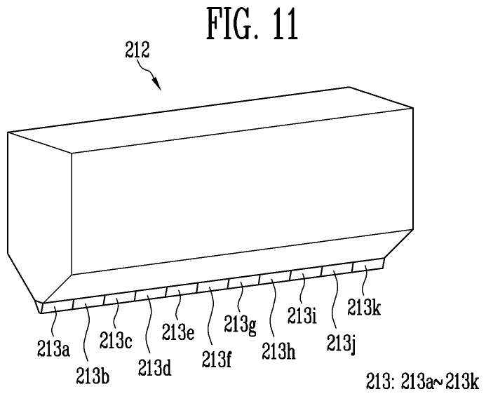

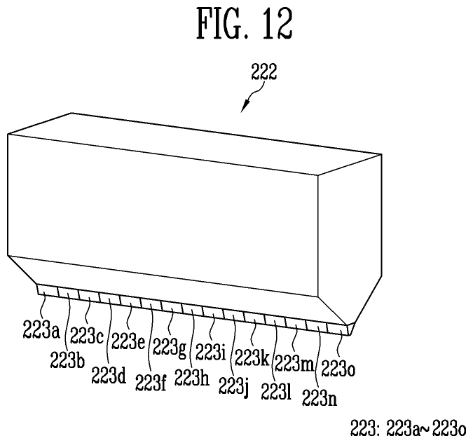

FIG. 9 illustrates a schematic perspective view of a coating apparatus 1 for forming the cover panel CVP of FIG. 8, FIG. 10 schematically illustrates that a coating solution COL is applied by a first supplier 210 of FIG. 9, FIG. 11 illustrates a schematic perspective view of a first slit head 212 of FIG. 9, and FIG. 12 illustrates illustrated schematic perspective view of a second slit head 222 of FIG. 9.

Referring to FIG. 9 to FIG. 12, the coating apparatus 1 according to the embodiments is installed on a base frame, and it may include a stage STG on which the display panel DP is loaded thereon, a supplier 200 for applying the coating solution COL to an application area of the display panel DP loaded on the stage STG, and a driving part 100 for moving the supplier 200. In addition, the coating apparatus 1 may further include a control part for controlling overall operations of the apparatus.

The coating solution COL is a base material of the cover panel CVP, and may include a curable resin that is cured, for example, by heat or light.

The display panel DP may be the display panel DP described with reference to FIG. 3 to FIG. 8. The display panel DP may be seated on the stage STG so that the second surface SF2 (or the rear surface) of the substrate SUB may face upward (or may face the supplier 200).

The supplier 200 may discharge (or supply) the coating solution COL to the application area of the display panel DP (for example, the second surface SF2 (or the rear surface) of the substrate SUB). In the embodiments, the supplier 200 may include the first supplier 210 and the second supplier 220 that are spaced apart from each other and move in different directions to supply the coating solution COL to the application area. For example, the first supplier 210 may supply the coating solution COL to the application area while moving in a first direction DR1, and the second supplier 220 may supply the coating solution COL to the application area while moving in a second direction DR2 crossing the first direction DR1. However, the present disclosure is not limited thereto, and the first supplier 210 may supply the coating solution COL to the application area while moving in the second direction DR2, and the second supplier 220 may supply the coating solution COL to the application area while moving in the first direction DR1 crossing the second direction DR2.

The first supplier 210 may include a first coating solution supplier 211, a first slit head 212, and a first nozzle part 213.

The first coating solution supplier 211 may provide a quantitative amount of the coating solution COL to the first slit head 212. The first coating solution supplier 211 may include a storage tank 211b for storing the coating solution COL, and a pump part 211a for pumping and supplying the coating solution COL at a constant pressure and flow rate from the storage tank 211b.

The first slit head 212 is a device for receiving the coating solution COL from the first coating solution supplier 211 and applying the coating solution COL on the rear surface (or the second surface SF2 of the substrate SUB) of the display panel DP that is a coating object, and may be connected to a supply line 211c of the first coating solution supplier 211. Inside of a main body forming the exterior of the first slit head 212, a supply pipe 212a connected to the supply line 211c through the main body and a storage part 212b for temporarily storing the coating solution COL may be positioned. One end of the supply pipe 212a may be connected to the supply line 211c that transports the coating solution COL from the first coating solution supplier 211, and the other end of the supply pipe 212a may be connected to the storage part 212b. Accordingly, the coating solution COL may flow into the storage part 212b through the supply pipe 212a. The configuration of the first slit head 212 is not limited to the above-described embodiments.

The first nozzle part 213 from which the coating solution COL stored in the storage part 212b is discharged may be positioned on a lower surface of the first slit head 212.

The first nozzle part 213 may be connected to the storage part 212b of the first slit head 212. The first nozzle part 213 may include a plurality of first nozzles 213a to 213k. The first nozzles 213a to 213k may be located on the lower surface of the first slit head 212 in an inline form, but are not limited thereto. Each of the first nozzles 213a to 213k may be individually controlled according to a signal applied to the corresponding nozzle to spray the coating solution COL to an application area (e.g., a set or predetermined application area). Each of the first nozzles 213a to 213k may be positioned to be spaced apart from the adjacent first nozzles. The first nozzles 213a to 213k may be provided in a slit type extending from a bottom surface of the first slit head 212 along a longitudinal direction of the first slit head 212 to apply the coating solution COL to an application area (e.g., a set or predetermined application area) (for example, the second surface SF2 of the substrate SUB).

The first nozzle part 213 may include an actuator for individually controlling and driving each of the first nozzles 213a to 213k. The first nozzle part 213 may individually control each of the first nozzles 213a to 213k by the actuator to apply the coating solution COL to a target area.

The second supplier 220 may include a second coating solution supplier 221, a second slit head 222, and a second nozzle part 223.

The second coating solution supplier 221 may provide a quantitative amount of the coating solution COL to the second slit head 222. Like the first coating solution supplier 211, the second coating solution supplier 221 may include a storage part for storing the coating solution COL and a pump part for pumping and supplying the coating solution COL at a constant pressure and flow rate from the storage part.

The second slit head 222 may receive the coating solution COL from the second coating solution supplier 221 to apply the coating solution COL on the rear surface of the display panel DP that is a coating object. The second slit head 222 may have substantially the same configuration as the above-described first slit head 212.

The second nozzle part 223 from which the coating solution COL is discharged may be positioned on a bottom surface of the second slit head 222.

The second nozzle part 223 may be connected to a storage part of the second slit head 222. The second nozzle part 223 may include a plurality of second nozzles 223a to 223o.

The second nozzles 223a to 223o may be located on the lower surface of the second slit head 222 in an inline form, but are not limited thereto. Each of the second nozzles 223a to 223o may be individually controlled according to a signal applied to the corresponding nozzle to spray the coating solution COL to a target area. Each of the second nozzles 223a to 223o may be positioned to be spaced apart from the adjacent second nozzles. The second nozzles 223a to 223o may be provided in a slit type extending from a bottom surface of the second slit head 222 in a longitudinal direction of the second slit head 222 to apply the coating solution COL to an application area (for example, the second surface SF2 of the substrate SUB).

The second nozzle part 223 may include an actuator for individually controlling and driving each of the second nozzles 223a to 223o. The second nozzle part 223 may individually control each of the second nozzles 223a to 223o by the actuator to apply the coating solution COL to a target area.

The driving part 100 may include a first moving part 110, a second moving part 120, and a third moving part 130 for moving the first and second suppliers 210 and 220. The first moving part 110 may move each of the first and second suppliers 210 and 220 in the first direction DR1 (for example, a Y-axis direction), the second moving part 120 may move each of the first and second suppliers 210 and 220 in the second direction DR2 (for example, an X-axis direction), and the third moving part 130 may move each of the first and second suppliers 210 and 220 in the third direction DR3 (for example, a Z-axis direction), but the present disclosure is not limited thereto.

A linear movement mechanism including an actuator pneumatically or hydraulically operated, a linear motor, or a ball screw may be applied to each of the first moving part 110, the second moving part 120, and the third moving part 130.

The above-described first supplier 210 applies the coating solution COL on the rear surface of the display panel DP (or the second surface SF2 of the substrate SUB) while moving along the first direction DR1 by the first, second, and third moving parts 110, 120, and 130. The first supplier 210 applies the coating solution COL while avoiding a specific area (for example, an area in which the first to third sensors SR1, SR2, and SR3 are inserted (or mounted)) of the rear surface of the display panel DP (or the second surface SF2 of the substrate SUB) by individually controlling each of the first nozzles 213a to 213k.

After the first supplier 210 applies the coating solution COL on the rear surface of the display panel DP (or the second surface SF2 of the substrate SUB), the second supplier 220 applies the coating solution COL to an uncoated area to which the coating solution COL is not applied by the first supplier 210. Specifically, the above-described second supplier 220 applies the coating solution COL on the uncoated area while avoiding a specific area of the rear surface of the display panel DP (or the second surface SF2 of the substrate SUB) while moving along the second direction DR2 by the first, second, and third moving parts 110, 120, and 130.

Hereinafter, a method of forming the cover panel CVP on the rear surface of the display panel DP (or the second surface SF2 of the substrate SUB) by using the coating apparatus 1 described above will be described with reference to FIG. 13A to FIG. 13K.

FIG. 13A to FIG. 13K illustrate schematic drawings for sequentially explaining a method of forming the cover panel CVP by using the coating apparatus 1 of FIG. 9.

For convenience, in FIG. 13A to FIG. 13F, the first slit head 212 and the first nozzle part 213 are shown to be positioned at an upper side of the substrate SUB, but when the first slit head 212 substantially moves on the substrate SUB along the first direction DR1, the first nozzle part 213 may face the second surface SF2 (or the rear surface) of the substrate SUB.

For convenience, in FIG. 13G to FIG. 13J, the second slit head 222 and the second nozzle part 223 are shown to be positioned at a right side of the substrate SUB, but when the second slit head 222 substantially moves on the substrate SUB along the second direction DR2, the second nozzle part 223 may face the second surface SF2 (or the rear surface) of the substrate SUB.

Referring to FIG. 1 to FIG. 13A, when the display panel DP is seated on the stage STG so that the second surface SF2 (or the rear surface) of the substrate SUB faces upward, the first slit head 212 of the first supplier 210 is positioned at an upper portion of the substrate SUB by the first, second, and third moving parts 110, 120, and 130 to perform pre-preparation for applying the coating solution COL on the second surface SF2 of the substrate SUB.

The coating solution COL may include a curable resin that has adhesive properties and is cured by heat or light.

For example, the coating solution COL may include a thermosetting resin having adherence by causing a chemical reaction by heat. The thermosetting resin may include, for example, an epoxy resin, an amino resin, a phenol resin, a polyester resin, and the like composed of an organic material, but is not limited thereto. In some embodiments, the coating solution COL may include a curable resin composition including a thermal polymerization initiator that initiates a curing reaction by heat. The type of the thermal polymerization initiator is not particularly limited, but may include azo compounds such as 2,2′-azobis(2-methylbutyronitrile), 2,2′-azobis(isobutyronitrile), 2,2′-azobis(2,4-dimethylvaleronitrile), 4,4-azobis(4-cyanovaleric acid), 1,1′-azobis(cyclohexane carbonitrile) and 2,2′-azobis(4-methoxy-2,4-dimethyl valeronitrile); peroxide compounds such as tetrametbylbutylperoxy neo-decanoate (e.g., Perocta ND, NOF), bis(4-butycyclohexyl)peroxydicarbonate (e.g., Percota TCP, NOF), di-(2-ethylhexyl)peroxy carbonate, butylperoxy neo-decanoate (e.g., Perbutyl ND, NOF), di-n-propyl peroxydicarbonate (e.g., Peroyl NPP, NOF), di-isopropyl peroxy dicarbonate (e.g., Peroyl IPP, NOF), diethoxyethyl peroxydicarbonate (e.g., Peroyl EEP, NOF), diethoxylhexyl peroxydicarbonate (e.g., Peroyl OEP, NOF), hexyl peroxydicarbonate (e.g., Perhexyl ND, NOF), dimethoxybutyl peroxydicarbonate (e.g., Peroyl MBP, NOF), bis (3-metoxy-3-metoxybutyl) peroxydicarbonate (e.g., Peroyl SOP, NOF), dibutyl peroxy dicarbonate, diacetyl peroxydicarbonate, dimyristyl peroxydicarbonate, 1,1,3,3-tetramethylbutyl peroxypivalate, hexyl peroxypivalate (e.g., Perhexyl PV, NOF), butyl peroxypivalate (e.g., Perbutyl, NOF), 3,5,5-trimethylhexanol peroxide (e.g., Peroyl 355, NOF), 1,1-dimethyl-3-hydroxybutyl peroxy-neodecanoate (e.g., Luperox 610M75, Altofina), t-amyl peroxy-neodecanoate (e.g., Luperox 546M75, Atofina), t-butyl peroxy-neodecanoate (e.g., Luperox 10M75, Atofina), t-butyl peroxy-neoheptanoate, t-butyl peroxy-pivalate, t-amyl peroxy-2-ethylhexanoate, lauroyl peroxide, dilauroyl peroxide, didecanoyl peroxide, benzoyl peroxide, dibenzoyl peroxide, 2,2-bis(tert-butylperoxy)butane, 1,1-bis(tert-butyl peroxylcyclohexane, 2,5-bis(tert-butylperoxy)-1-m ethylethyl)benzene, 1,1-bis(tert-butylperoxy)-3,3,5-trim ethylcyclohexane, tert-butyl hydroperoxide, tert-butyl peroxide, tert-butyl peroxybenzoate, tert-butylperoxy isopropyl carbonate, cumene hydroperoxide, dicumyl peroxide, lauroyl peroxide and 2,4-pentanedione peroxide; tert-butyl peracetate; peracetic acid; or potassium persulfate, but is not limited thereto.

As another example, the coating solution COL may include a photocurable resin including a photopolymerization initiator that is crosslinked and cured by light such as UV. The type of the photopolymerization initiator is not particularly limited, but may include α-hydroxy ketone compound (e.g., IRGACURE 184, IRGACURE500, IRGACURE 2959, DAROCUR 1173, Ciba Specialty Chemicals), phenyl glyoxylate compound (e.g., IRGACURE 754, DAROCUR MBF, Ciba Specialty Chemicals), benzyldimethyl-ketal compound (e.g., IRGACURE 651, Ciba Specialty Chemicals), α-amino ketone compound (e.g., IRGACURE 369, IRGACURE 907, IRGACURE 1300, Ciba Specialtyr Chemicals), mono acyl phosphine compound (MAPO) (e.g., DAROCUR TPO, Ciba Specialty Chemicals), bisacyl phosphine compound (BAPO) (e.g., IRGACURE 819, IRGACURE 819DW, Ciba Specialty Chemicals), phosphine oxide compound (e.g., IRGACURE 2100, Ciba Specialty Chemicals), metallocene compound (e.g., IRGACURE 784, Ciba Specialty Chemicals), iodonium salt (e.g., IRGACURE 250, Ciba Specialty Chemicals), or at least any one compound thereof (e.g., DAROCUR 4265, IRGACURE 2022, IRGACURE 1300, IRGACURE 2005, IRGACURE 2010, IRGACURE 2020, Ciba Specialty Chemicals), but is not limited thereto.

Then, the first slit head 212 is moved in the first direction DR1 (for example, a Y-axis direction or a vertical direction) by the first moving part 110 to apply the coating solution COL to a target area (or a predetermined area) in the second surface SF2 of the substrate SUB. In the embodiments, the second surface SF2 of the substrate SUB may include a first edge ED1 and a second edge ED2 facing each other in the first direction DR1, and a third edge ED3 and a fourth edge ED4 facing each other in the second direction DR2 crossing the first direction DR1.

In the embodiments, while the first slit head 212 moves from the first edge ED1 of the second surface SF2 of the substrate SUB along the first direction DR1 to the second edge ED2 as shown by an arrow shown in FIG. 13A, it may apply the coating solution COL to the target area (or the predetermined area). When areas A1, A2, and A3 overlapping the sensor SR are not positioned in the target area, (1-1)-th to (1-3)-th nozzles 213a, 213b, and 213c of the first nozzle part 213 positioned to correspond to the target area may be turned on to apply the coating solution COL to the target area.

When the first slit head 212 moves from the first edge ED1 of the second surface SF2 of the substrate SUB along the first direction DR1 to the second edge ED2, each of the (1-1)-th to (1-3)-th nozzles 213a, 213b, and 213c may be turned on by an actuator that individually controls the corresponding nozzle, and the remaining first nozzles 213d to 213k except for the (1-1)-th to (1-3)-th nozzles 213a, 213b, and 213c may be maintained in an turned-off state by an actuator that individually controls the corresponding nozzle.

When the coating solution COL is applied to the target area by the (1-1)-th to (1-3)-th nozzles 213a, 213b, and 213c, the first slit head 212 may be moved from the second edge ED2 of the second surface SF2 of the substrate SUB to the first edge ED1 along an opposite direction of the first direction DR1 by the first, second, and third moving parts 110, 120, and 130 and then may wait.

Referring to FIG. 1 to FIG. 13B, while the first slit head 212 is moved from the first edge ED1 of the second surface SF2 of the substrate SUB along the first direction DR1 to the second edge ED2 by the first moving part 110, it applies the coating solution COL to a target area (or a preset area). When the second area A2 of the areas A1, A2, and A3 overlapping the sensor SR is positioned in the target area, the (1-4)-th nozzle 213d of the first nozzle part 213 positioned to correspond to the target area may be turned on after the first slit head 212 has passed through the second area A2 to apply the coating solution COL to the target area as shown by a arrow shown in FIG. 13B. When the first slit head 212 moves along the first direction DR1 and passes the second area A2, the (1-4)-th nozzle 213d may be turned on by an actuator that individually controls the corresponding nozzle to apply the coating solution COL to the target area.

When the first slit head 212 moves from the first edge ED1 of the second surface SF2 of the substrate SUB along the first direction DR1 to the second edge ED2, the (1-4)-th nozzle 213d may be turned on by an actuator that individually controls the corresponding nozzle, and each of the first nozzles 213a to 213c and 213e to 213k excluding the (1-4)-th nozzles 213d may be maintained in an turned-off state by an actuator that individually controls the corresponding nozzle. Accordingly, the first slit head 212 may apply the coating solution COL to the target area while avoiding the second area A2. The coating solution COL may not be applied to the second area A2, and one area of the second surface SF2 of the substrate SUB positioned above the second area A2 in the first direction DR1.

In the embodiments, the second area A2 may be one area of the second surface SF2 of the substrate SUB overlapping the second sensor SR2 inserted (or mounted) in the second opening OP2 of the cover panel CVP.

When the coating solution COL is applied to the target area by the (1-4)-th nozzles 213d, the first slit head 212 may be moved from the second edge ED2 of the second surface SF2 of the substrate SUB to the first edge ED1 along an opposite direction of the first direction DR1 by the first, second, and third moving parts 110, 120, and 130 and then may wait.

Referring to FIG. 1 to FIG. 13C, while the first slit head 212 is moved from the first edge ED1 of the second surface SF2 of the substrate SUB along the first direction DR1 to the second edge ED2 by the first moving part 110, it applies the coating solution COL to a target area (or a preset area). When the first and third areas A1 and A3 of the areas A1, A2, and A3 overlapping the sensor SR are positioned on the same line as the target area in the first direction DR1, the (1-5)-th and (1-6)-th nozzles 213e and 213f of the first nozzle part 213 positioned to correspond to the target area may be turned on after the first slit head 212 has passed through the first area A1 to apply the coating solution COL to the target area as shown by a arrow shown in FIG. 13C. When the first slit head 212 moves along the first direction DR1 and passes through the first area A1, each of the (1-5)-th and (1-6)-th nozzles 213e and 213f may be turned on by an actuator that individually controls the corresponding nozzle to apply the coating solution COL to the target area, and may be turned off by the actuator before the third area A3 appears. While the coating solution COL is applied to the target area by the (1-5)-th and (1-6)-th nozzles 213e and 213f, each of the remaining first nozzles 213a to 213d and 213g to 213k except for the (1-5)-th and (1-6)-th nozzles 213e and 213f may be maintained in an turned-off state by an actuator that individually controls the corresponding nozzle. Accordingly, the coating solution COL may be applied to the target area while avoiding the first area A1 and the third area A3. The coating solution COL may not be applied to the first area A1, and one area of the second surface SF2 of the substrate SUB positioned above the first area A1 in the first direction DR1. In addition, the coating solution COL may not be applied to the third area A3, and the other area of the second surface SF2 of the substrate SUB positioned below the third area A3 in the first direction DR1.

In the embodiments, the first area A1 may be one area of the second surface SF2 of the substrate SUB overlapping the first sensor SR1 inserted (or mounted) in the first opening OP1 of the cover panel CVP, and the third area A3 may be one area of the second surface SF2 of the substrate SUB overlapping the third sensor SR3 inserted (or mounted) in the third opening OP3 of the cover panel CVP.

When the coating solution COL is applied to the target area by the (1-5)-th and (1-6)-th nozzles 213e and 213f, the first slit head 212 may be moved from the second edge ED2 of the second surface SF2 of the substrate SUB to the first edge ED1 along an opposite direction of the first direction DR1 by the first, second, and third moving parts 110, 120, and 130, and then may be moved in a direction opposite of the second direction DR2 by the second moving part 120 to wait.

Referring to FIG. 1 to FIG. 13D, while the first slit head 212 is moved from the first edge ED1 of the second surface SF2 of the substrate SUB along the first direction DR1 to the second edge ED2 by the first moving part 110, it applies the coating solution COL to a target area (or a preset area). When the third area A3 is positioned on the same line as the target area in the first direction DR1, the (1-6)-th nozzle 213f of the first nozzle part 213 positioned to correspond to the target area may be turned on by the actuator that individually controls the corresponding nozzle to apply the coating solution COL to the target area as shown by an arrow shown in FIG. 13D when the first slit head 212 moves along the first direction DR1, and it may be turned off by the actuator just before the third area A3 appears to not apply the coating solution COL to the third area A3. While the coating solution COL is applied to the target area by the (1-6)-th nozzle 213f, each of the remaining first nozzles 213a to 213e and 213g to 213k except for the (1-6)-th nozzle 213f may be maintained in an turned-off state by an actuator that individually controls the corresponding nozzle. Accordingly, the coating solution COL may be applied to the target area while avoiding the third area A3. The coating solution COL may not be applied to the third area A3, and one area of the second surface SF2 of the substrate SUB positioned below the third area A3 in the first direction DR1.

Depending on an area in which the coating solution COL is applied on the second surface SF2 of the substrate SUB, a gap G (or a space) may be generated between the coating solutions COL such that an unwanted second surface SF2 of the substrate SUB may be exposed, but due to the surface tension of the coating solution COL, the coating solution COL may move to the gap G to fill the gap G. Accordingly, the second surface SF2 of the substrate SUB may not be exposed.

When the coating solution COL is applied to the target area by the (1-6)-th nozzles 213f, the first slit head 212 may be moved from the second edge ED2 of the second surface SF2 of the substrate SUB to the first edge ED1 along an opposite direction of the first direction DR1 by the first, second, and third moving parts 110, 120, and 130 and then may wait.

Referring to FIG. 1 to FIG. 13E, while the first slit head 212 is moved from the first edge ED1 of the substrate SUB along the first direction DR1 to the second edge ED2 by the first moving part 110, it applies the coating solution COL to a target area (or a preset area). When areas A1, A2, and A3 overlapping the sensor SR are not positioned in the target area, each of the (1-7)-th to (1-10)-th nozzles 213g, 213h, 213i, and 213j of the first nozzle part 213 positioned to correspond to the target area may be turned on to apply the coating solution COL to the target area. While the first slit head 212 moves along the first direction DR1, each of the (1-7)-th to (1-10)-th nozzles 213g, 213h, 213i, and 213j may be turned on by an actuator that individually controls that corresponding nozzle to apply the coating solution COL to the target area as shown by an arrow shown in FIG. 13E, and each of the first nozzles 213a to 213f and 213k except for the (1-7)-th to (1-10)-th nozzles 213g, 213h, 213i, and 213j may be maintained in an turned-off state by an actuator that individually controls the corresponding nozzle.

When the coating solution COL is applied to the target area by the (1-7)-th to (1-10)-th nozzles 213g, 213h, 213i, and 213j, the first slit head 212 may be moved from the second edge ED2 of the second surface SF2 of the substrate SUB to the first edge ED1 along an opposite direction of the first direction DR1 by the first, second, and third moving parts 110, 120, and 130 and then may wait.

Referring to FIG. 1 to FIG. 13F, when the process of applying the coating solution COL on the second surface SF2 of the substrate SUB by the first slit head 212 is completed, the coating solution COL may not be applied to the first area A1, the second area A2, and the third area A3 overlapping the sensor SR. In addition, an area B (hereinafter, referred to as an “uncoated area”) of the second surface SF2 of the substrate SUB to which the coating solution COL is not applied by the first slit head 212 may exist.

The uncoated area B may include a first uncoated area B1, a second uncoated area B2, a third uncoated area B3, and a fourth uncoated area B4 positioned adjacent to first area A1, the second area A2, and the third area A3. For example, the first uncoated area B1 may be positioned above the first area A1, the second uncoated area B2 may be positioned at the left of the first area A1, the third uncoated area B3 may be positioned above the second area A2, and the fourth uncoated area B4 may be positioned below the third area A3.

Referring to FIG. 1 to FIG. 13G, when the above-described uncoated area B exists, the second slit head 222 is positioned at the right side of the substrate SUB by the first, second, and third moving parts 110, 120, and 130 to perform pre-preparation for applying the coating solution COL to the uncoated area B. Then, while the second slit head 222 is moved in the second direction DR2 (for example, the X-axis direction or the horizontal direction) by the second moving part 120, it applies the coating solution COL to the uncoated area B. The coating solution COL may be the same as the coating solution COL applied to the second surface SF2 of the substrate SUB by the first slit head 212 and the first nozzle part 213.

In the embodiments, as the second slit head 222 moves from the third edge ED3 of the second surface SF2 of the substrate SUB to the fourth edge ED4 along the second direction DR2, the second nozzle part 223 may apply the coating solution COL to the target area as shown by an arrow shown in FIG. 13G, for example, the first uncoated area B1. The (2-1)-th nozzle 223a of the second nozzle part 223 positioned to correspond to the first uncoated area B1, when the second slit head 222 moves along the second direction DR2 to face the first uncoated area B1, may be turned on by an actuator that individually controls the corresponding nozzle to apply the coating solution COL to the first uncoated area B1. When the coating solution COL is applied to the first uncoated area B1, the (2-1)-th nozzle 223a may be turned on by an actuator that individually controls the corresponding nozzle, and each of the remaining second nozzles 223b to 223o except for the (2-1)-th the nozzle 223a may be maintained in a turned-off state by an actuator that individually controls the corresponding nozzle. When the application of the coating solution COL to the first uncoated area B1 is completed, the (2-1)-th nozzle 223a may be turned off by the actuator that individually controls the corresponding nozzle.

When the coating solution COL is applied to the first uncoated area B1 by the (2-1)-th nozzle 223a, the second slit head 222 may be moved from the fourth edge ED4 of the second surface SF2 of the substrate SUB to the third edge ED3 thereof along a direction opposite to the second direction DR2 by the first, second, and third moving parts 110, 120, and 130, and then it may be moved by the first moving part 110 in the first direction DR1 (for example, downward direction) to wait.

Referring to FIG. 1 to FIG. 13H, while the second slit head 222 is moved from the third edge ED3 of the second surface SF2 of the substrate SUB along the second direction DR2 to the fourth edge ED4 thereof by the second moving part 120, the second nozzle part 223 applies the coating solution COL to the second uncoated area B2. When the second uncoated area B2 and the first area A1 are positioned on the same line in the second direction DR2 and when the first area A1 is adjacent to the second slit head 222 than the second uncoated area B2, the (2-1)-th nozzle 223a of the second nozzle part 223 positioned to correspond to the second non-applied area B2, when the second slit head 222 moves in the second direction DR2, may pass the first area A1 to be turned on to apply the coating solution COL to the second uncoated area B2. When the second slit head 222 moves along the second direction DR2 and passes the first area A1, the (2-1)-th nozzle 223a is turned on by an actuator that individually controls the nozzle to apply the coating solution COL to the second uncoated area B2 as shown by an arrow shown in FIG. 13H, and it is turned off by the actuator after the application of the coating solution COL is completed. Each of the second nozzles 223b to 223o except for the (2-1)-th nozzle 223a is maintained in an turned-off state by an actuator that individually controls the corresponding nozzle while the second slit head 222 moves.

When the coating solution COL is applied to the second uncoated area B2 by the (2-1)-th nozzles 223a, the second slit head 222 may be moved from the fourth edge ED4 of the second surface SF2 of the substrate SUB to the third edge ED3 along an opposite direction of the second direction DR2 by the first, second, and third moving parts 110, 120, and 130, and then may wait.

Referring to FIG. 1 to FIG. 13I, when the second slit head 222 is moved from the third edge ED3 of the second surface SF2 of the substrate SUB along the second direction DR2 to the fourth edge ED4 thereof by the second moving part 120, the second nozzle part 223 may apply the coating solution COL to the third uncoated area B3 as shown by the arrow shown in FIG. 13I. The (2-2)-th nozzle 223b of the second nozzle part 223 positioned to correspond to the third uncoated area B3, when the second slit head 222 moves along the second direction DR2 to face the third uncoated area B3, may be turned on by an actuator that individually controls the (2-2)-th nozzle 223b to apply the coating solution COL to the third uncoated area B3. While the (2-2)-th nozzle 223b is turned on by the actuator that individually controls the corresponding nozzle, each of the second nozzles 223a and 223c to 223o except the (2-2)-th nozzle 223b may be maintained in a turned-off state by the actuator that individually controls the corresponding nozzle. When the application of the coating solution COL to the third uncoated area B3 is completed, the (2-2)-th nozzle 223b may be turned off by the actuator that individually controls the corresponding nozzle.

When the coating solution COL is applied to the third uncoated area B3 by the (2-2)-th nozzle 223b, the second slit head 222 may be moved from the fourth edge ED4 of the second surface SF2 of the substrate SUB to the third edge ED3 thereof along a direction opposite to the second direction DR2 by the first, second, and third moving parts 110, 120, and 130, and then it may be moved by the first moving part 110 in the opposite direction of the first direction DR1 (for example, upward direction) to wait.

Referring to FIG. 1 to FIG. 13J, when the second slit head 222 is moved from the third edge ED3 of the second surface SF2 of the substrate SUB along the second direction DR2 to the fourth edge ED4 thereof by the second moving part 120, the second nozzle part 223 may apply the coating solution COL to the fourth uncoated area B4 as shown by the arrow shown in FIG. 13J. Each of the (2-13)-th to (2-15)-th nozzles 223m, 223n, and 223o of the second nozzle part 223 positioned to correspond to the fourth uncoated area B4 may be turned on by an actuator that individually controls each of the (2-13)-th to (2-15)-th nozzles 223m, 223n, and 223o to apply the coating solution COL to the fourth uncoated area B4, when the second slit head 222 moves along the second direction DR2 to face the fourth uncoated area B4. While each of the (2-13)-th to (2-15)-th nozzles 223m, 223n, and 223o is turned on by an actuator that individually controls the corresponding nozzle, each of the remaining second nozzles 223a to 2231 excluding the (2-13)-th to (2-15)-th nozzles 223m, 223n, and 223o may be maintained in an turned-off state by an actuator that individually controls the corresponding nozzle.

When the coating solution COL is applied to the fourth uncoated area B4 by each of the (2-13)-th to (2-15)-th nozzles 223m, 223n, and 223o, the second slit head 222 may be moved from the fourth edge ED4 of the second surface SF2 of the substrate SUB to the third edge ED3 along an opposite direction of the second direction DR2 by the first, second, and third moving parts 110, 120, and 130 to wait.

As described above, while avoiding the first area A1, the second area A2, and the third area A3 by the first slit head 212 and the second slit head 222, the coating solution COL may be applied on the second surface SF2 (or the rear surface) of the substrate SUB.

Referring to FIG. 1 to FIG. 13K, after moving the display panel DP including the substrate SUB coated with the coating solution COL on the second surface SF2 to the curing chamber, the coating solution COL is cured to form the cover panel CVP including at least one or more opening OP. For example, the coating solution COL may be cured by applying heat or light (for example, ultraviolet (UV)).

The opening OP may include the first opening OP1 corresponding to the first area A1, the second opening OP2 corresponding to the second area A2, and the third opening OP3 corresponding to the third area A3. The first sensor SR1 described with reference to FIG. 3 may be inserted (or mounted) into the first opening OP1, the second sensor SR2 described with reference to FIG. 3 may be inserted (or mounted) into the second opening OP2, and the third sensor SR3 described with reference to FIG. 3 may be inserted (or mounted) into the third opening OP3.

Due to the material characteristics of the cover panel CVP finally formed on the second surface SF2 (or the rear surface) of the substrate SUB, the cover panel CVP may protect the display panel DP (or the substrate SUB) from external impact and the like, and may shield the electromagnetic wave or absorb the electromagnetic wave to improve reliability of the display panel DP. In addition, the cover panel CVP may dissipate heat generated from the heat generating members located on the first surface SF1 of the substrate SUB. Accordingly, the heat generating members located adjacent to the cover panel CVP may easily dissipate the heat generated during the driving process, so that they may be stably driven even when the driving time ends. The heat generating members may include the pixel circuit layer PCL and the display element layer DPL, but are not limited thereto, and may include all components that generate heat during operation.

According to the above-described embodiments, the cover panel CVP including the curable resin formed on the second surface SF2 of the substrate SUB replaces respective functions of a cushion layer and/or an embossing layer (or a first layer) of a conventional display device that is formed on the rear surface of the display panel DP to protect the display panel DP from external impact and the like, an antistatic layer (or a second layer) of a conventional display device that is formed on the rear surface of the display panel DP to block electromagnetic waves, and a heat dissipation layer (or a third layer) of a conventional display device that is formed on the rear surface of the display panel DP to dissipate heat generated by the display panel DP, so that the cushion layer and/or the embossing layer, the antistatic layer, and the heat dissipation layer may be omitted. Accordingly, the manufacturing cost of the display device DD may be reduced, and the manufacturing efficiency thereof may be improved.

In addition, according to the above-described embodiments, while avoiding a specific area (for example, an area in which the sensor SR is inserted (mounted)) by using the first slit head 212 and the second slit head 222 moving in a direction crossing each other and the individually controlled first and second nozzles 213a to 213k and 223a to 223o, the coating solution COL may be uniformly applied on the second surface SF2 of the substrate SUB.

In FIG. 13A to FIG. 13F, the first slit head 212 is shown to have a length corresponding to the first edge ED1 (or the second edge ED2) of the second surface SF2 of the substrate SUB, but is not limited thereto. In some embodiments, the first slit head 212 may have a length corresponding to a portion of the first edge ED1. In this case, the first slit head 212 may be moved in the opposite direction (for example, the right direction) of the second direction DR2 by the second moving part 120 after applying the coating solution COL to the target area.

In FIG. 13G to FIG. 13J, the second slit head 222 is shown to have a length corresponding to the third edge ED3 (or the fourth edge ED4) of the second surface SF2 of the substrate SUB, but is not limited thereto. In some embodiments, the second slit head 222 may have a length corresponding to a portion of the third edge ED3. In this case, the second slit head 222 may be moved in the first direction DR1 (for example, the downward direction) by the first moving part 110 after the coating solution COL is applied to the uncoated area B.

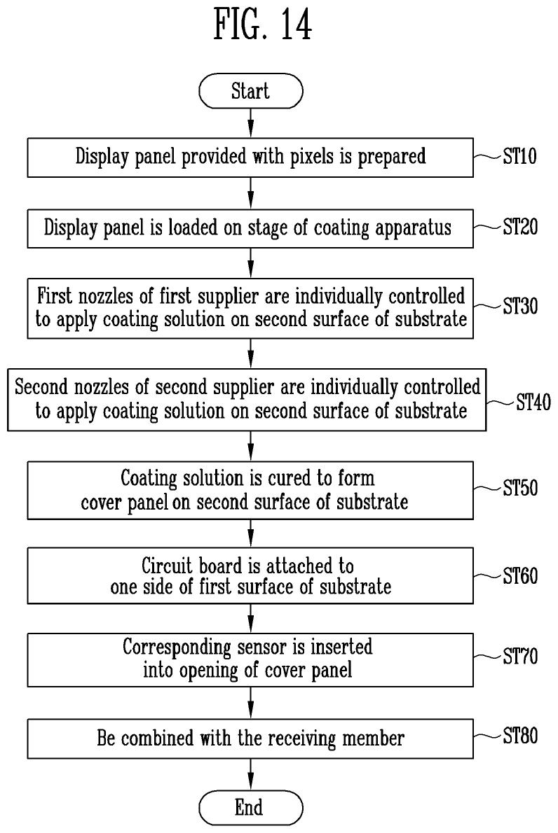

FIG. 14 illustrates a flowchart of a manufacturing method of the display device DD of FIG. 2.

Referring to FIG. 1 to FIG. 14, the display panel DP provided with a plurality of pixels PXL is prepared (ST10).

The plurality of pixels PXL may be provided on the first surface SF1 (or the upper surface) of the substrate SUB of the display panel DP.

In the above-described step, the pixel circuit layer PCL, the display element layer DPL, the thin film encapsulation layer TFE, and the optical layer ARU may be formed on the first surface SF1 of the substrate SUB.

The display panel DP is loaded on the stage STG of the coating apparatus 1 so that the second surface SF2 (or the rear surface) of the substrate SUB faces upward (ST20).

While moving the first supplier 210 of the coating apparatus 1 in the first direction DR1, each of the first nozzles 213a to 213k of the first supplier 210 is individually controlled to apply the coating solution COL on the second surface SF2 of the substrate SUB while avoiding the areas A1, A2, and A3 overlapping the sensor SR (ST30).

While moving the second supplier 220 of the coating apparatus 1 in the second direction DR2, each of the second nozzles 223a to 223o of the second supplier 220 is individually controlled to apply the coating solution COL to the uncoated area B to which the coating solution COL is not applied by the first nozzles 213a to 213k while avoiding the areas A1, A2, and A3 (ST40).

The display panel DP including the substrate SUB coated with the coating solution COL may be moved to a curing chamber.

The coating solution COL is cured to form the cover panel CVP including the first opening OP1, the second opening OP2, and the third opening OP3 on the second surface SF2 of the substrate SUB (ST50).

The circuit board FB is attached to one side of the first surface SF1 of the substrate SUB (ST60).

The circuit board FB may be electrically connected to the printed circuit board PB through the conductive adhesive member ACF.

The corresponding sensor SR is inserted (or mounted) into the opening OP of the cover panel CVP (ST70).

For example, the first sensor SR1 (for example, a camera) is inserted into the first opening OP1 of the cover panel CVP, the second sensor SR2 (for example, an infrared sensor) is inserted into the second opening OP2 of the cover panel CVP, and the third sensor SR3 (for example, a fingerprint recognition sensor) is inserted into the third opening OP3 of the cover panel CVP.

The cover panel CVP formed on the second surface SF2 of the substrate SUB are combined with the receiving member BC (ST80).

While aspects of some embodiments of the present disclosure have been shown and described with reference to certain embodiments thereof, it will be understood by those skilled in the art that various changes in forms and details may be made therein without departing from the spirit and scope of the present disclosure as defined by the appended claims and their equivalents.

Therefore, the technical scope of the present disclosure may be determined by on the technical scope of the accompanying claims, and their equivalents.

What is claimed is:

1. A display device comprising:
a display panel that includes a substrate including a display area and a non-display area and a plurality of pixels in the display area;
a cover panel directly on a rear surface of the substrate and including an opening exposing at least one area of the substrate;
a sensor provided within the opening of the cover panel;
a circuit board coupled to one side of an upper surface of the substrate and electrically connected to the pixels; and
a receiving member configured to receive the display panel, the cover panel, and the circuit board,
wherein the cover panel includes a photo-curable resin or a thermo-curable resin.

2. The display device of claim 1, wherein the sensor includes at least one of a camera, a proximity sensor, an illuminance sensor, a gesture sensor, an infrared sensor, a fingerprint recognition sensor, or a biometric sensor.

3. The display device of claim 1, wherein each of the pixels includes:
a pixel circuit layer including at least one transistor on an upper surface of the substrate; and
a display element layer including a light emitting element electrically connected to the transistor.

4. A manufacturing method of a display device, comprising:
preparing a display panel including a plurality of pixels on an upper surface of a substrate;
seating the display panel on a stage so that a rear surface of the substrate facing the upper surface of the substrate faces upward;
applying a coating solution on the rear surface of the substrate while avoiding a specific area on the rear surface of the substrate while a first supplier including a plurality of first nozzles is positioned above the rear surface of the substrate and moved along a first direction;
applying the coating solution on an uncoated area to which the coating solution is not applied by the first supplier while avoiding a specific area of the substrate while a second supplier including a plurality of second nozzles moves along a second crossing the first direction; and
curing the coating solution to form a cover panel including an opening corresponding to the specific area on the rear surface of the substrate.

5. The manufacturing method of the display device of claim 4, wherein the rear surface of the substrate includes a first edge and a second edge facing each other in the first direction, and includes a third edge and a fourth edge facing each other in a second direction.

6. The manufacturing method of the display device of claim 5, wherein the coating solution includes a curable resin.

7. The manufacturing method of the display device of claim 6, wherein the curable resin includes a thermosetting resin or a photocurable resin.

8. The manufacturing method of the display device of claim 7, wherein the first supplier includes a first slit head moving in the first direction, and the first nozzles positioned on a lower surface of the first slit head and individually controlled to apply the coating solution to a predetermined area on the rear surface of the substrate.

9. The manufacturing method of the display device of claim 8, wherein as the first slit head moves from the first edge to the second edge along the first direction, at least one or more of the first nozzles applies the coating solution to a predetermined area of the rear surface of the substrate.

10. The manufacturing method of the display device of claim 9, wherein based on the coating solution being applied to the predetermined area of the rear surface of the substrate, the first slit head moves from the second edge to the first edge and then moves in the second direction.

11. The manufacturing method of the display device of claim 10, wherein based on the first slit head moving from the first edge to the second edge along the first direction, the first nozzles are maintained in an turned-off state in the specific area, and at least one or more of the first nozzles is turned on after passing the specific area to apply the coating solution to a predetermined area of the rear surface of the substrate.

12. The manufacturing method of the display device of claim 10, wherein based on the specific area including a first specific area and a second specific area that are positioned on a same line in the first direction and are spaced apart from each other, and based on the first slit head moving from the first edge to the second edge along the first direction, the first nozzles are maintained in an turned-off state and then pass through the first specific area, and at least one or more of the first nozzles is turned on to apply the coating solution to the rear surface of the substrate and is turned off before the second specific area.

13. The manufacturing method of the display device of claim 10, wherein the second supplier includes a second slit head moving in the second direction, and the second nozzles positioned on a lower surface of the second slit head and individually controlled to apply the coating solution to the uncoated area.

14. The manufacturing method of the display device of claim 13, wherein as the second slit head moves from the third edge to the fourth edge along the second direction, at least one or more of the second nozzles applies the coating solution to the uncoated area.

15. The manufacturing method of the display device of claim 14, wherein based on the coating solution being applied to the uncoated area, the second slit head moves from the fourth edge to the third edge and then moves in the first direction.

16. The manufacturing method of the display device of claim 14, wherein based on the second slit head moving from the third edge to the fourth edge along the second direction, at least one of the second nozzles positioned to correspond to the uncoated area is turned on to apply the coating solution to the uncoated area.

17. The manufacturing method of the display device of claim 16, wherein based on the second slit head moving from the third edge to the fourth edge along the second direction, the second nozzles are maintained in an turned-off state in the specific area, and at least one of the second nozzles is turned on after passing the specific area to apply the coating solution to the uncoated area.

18. The manufacturing method of the display device of claim 4, wherein the first direction is one of a vertical direction and a horizontal direction, and the second direction is the other of the vertical direction and the horizontal direction.

19. The manufacturing method of the display device of claim 4, further comprising:
attaching a circuit board to one side of an upper surface thereof facing the rear surface of the substrate; and
inserting a sensor into the opening.

20. The manufacturing method of the display device of claim 19, wherein the sensor includes at least one of a camera, a proximity sensor, an illuminance sensor, a gesture sensor, an infrared sensor, a fingerprint recognition sensor, or a biometric sensor.
